(19) United States
(12) Patent Application Publication
(10) Pub. No.: US 2025/0255161 A1
(43) Pub. Date: Aug. 7, 2025

(54) DISPLAY DEVICE

(71) Applicant: Samsung Display Co., LTD., Yongin-si (KR)

(72) Inventors: Chan Young KIM, Yongin-si (KR); Sang Woo KANG, Yongin-si (KR); Seong Yong HWANG, Yongin-si (KR); Jin Su LEE, Yongin-si (KR); Seong Min CHO, Yongin-si (KR)

(21) Appl. No.: 18/903,852

(22) Filed: Oct. 1, 2024

(30) Foreign Application Priority Data
Feb. 1, 2024 (KR) 10-2024-0015875

(51) Int. Cl. H10K 59/80; H10K 59/131; H10K 59/35

(52) U.S. Cl. CPC H10K 59/8792; H10K 59/131; H10K 59/35

(57) ABSTRACT

A display device includes, a first display area around a second display area, a plurality of first openings in the first and second display areas and having light emitting elements therein, a plurality of second and third openings in the second display area, in which the light emitting element is not located, and having a smaller size than the first opening, a light blocking layer including first holes overlapping the first openings, second holes overlapping the plurality of second openings, and third holes around the light blocking pattern that overlaps the third opening, and a plurality of color filters in the first display area and the second display area and overlapping the plurality of first holes, wherein the number of the first holes in the second display area is greater than the number of the second holes and the third holes.

### CROSS-REFERENCE TO RELATED APPLICATION

The present application claims priority to and the benefit of Korean Patent Application No. 10-2024-0015875 filed on Feb. 1, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

With the advance of information-oriented society, more and more demands may be placed on display devices for displaying images in various ways. For example, display devices may be employed in various electronic devices such as smartphones, digital cameras, laptop computers, navigation devices, and smart televisions. The display device may be a flat panel display device such as a liquid crystal display device, a field emission display device and an organic light emitting display device. Among the flat panel display devices, in the light emitting display device, because each of pixels of a display panel includes a light emitting element capable of emitting light by itself, an image can be displayed without a backlight unit providing light to the display panel.

The above information disclosed in this Background section is only for enhancement of understanding of the background and therefore the information discussed in this Background section does not necessarily constitute prior art.

### SUMMARY

Aspects of some embodiments of the present disclosure include a display device having relatively improved performance of sensing light incident from the side of a display device.

However, aspects of the present disclosure are not restricted to those specifically set forth herein. The above and other aspects of the present disclosure will become more apparent to one of ordinary skill in the art to which the present disclosure pertains by referencing the detailed description of the present disclosure given below.

According to some embodiments of the present disclosure, there is provided a display device including, a first display area and a second display area around which the first display area is located, a plurality of first openings in the first display area and the second display area and in which light emitting elements are located, a plurality of second openings and third openings in the second display area, in which the light emitting element is not located, and having a smaller size than a size of the first opening, a light blocking layer including a plurality of first holes overlapping the plurality of first openings, a plurality of second holes overlapping the plurality of second openings, and a plurality of third holes around the light blocking pattern that at least partially overlaps the third opening, and a plurality of color filters in the first display area and the second display area and overlapping the plurality of first holes, wherein the number of the first holes in the second display area is greater than each of the number of the second holes and the number of the third holes.

According to some embodiments, the third holes are each arranged to surround the light blocking pattern.

According to some embodiments, the light blocking pattern has a circular shape in plan view, and the third hole has a quadrilateral edge in plan view.

According to some embodiments, the second holes have an elliptical shape in plan view, and the plurality of third holes are respectively on both sides of the light blocking pattern.

According to some embodiments, each of the third holes does not overlap the third opening.

According to some embodiments, the light blocking pattern has an elliptical shape in plan view, and both ends thereof in a major axis direction are in contact with the light blocking layer, and the third hole is formed between the light blocking pattern and the light blocking layer.

According to some embodiments, the third hole has a width which varies in the major axis direction of the light blocking pattern.

According to some embodiments, the number of the second holes in the second display area is smaller than the number of the third holes.

According to some embodiments, the number of the second holes in the second display area is greater than or equal to the number of the third holes.

According to some embodiments, the color filter does not overlap the second hole and the third hole.

According to some embodiments, the color filter does not overlap the second opening and the third opening.

According to some embodiments, the display device may further comprise a plurality of signal lines in the first display area and the second display area and extending in one direction, wherein the first opening partially overlaps the signal lines, and the second opening and the third opening do not overlap the signal lines.

According to some embodiments, a center line between a pair of adjacent signal lines among the plurality of signal lines is not parallel to a center line of the third opening.

According to some embodiments, the light blocking pattern is integrated with the light blocking layer to cover the third opening, and the third hole does not overlap the third opening.

According to some embodiments, some of the signal lines partially overlap the light blocking pattern.

According to some embodiments of the present disclosure, there is provided a display device including, a substrate including a first display area and a second display area around which the first display area is located, a plurality of pixel electrodes on the substrate and spaced apart from each other in the first display area and the second display area, a pixel defining layer including a plurality of first openings on the substrate and the pixel electrodes and overlapping the pixel electrode, and a plurality of second openings and third openings which do not overlap the pixel electrode in the second display area, an encapsulation layer on the pixel defining layer, a light blocking layer including a plurality of first holes on the encapsulation layer and overlapping the plurality of first openings, a plurality of second holes overlapping the plurality of second openings, and a plurality of third holes around a light blocking pattern overlapping the third opening, and a plurality of color filters on the light blocking layer and overlapping the first hole without overlapping the second hole and the third hole.

According to some embodiments, the third hole is defined as a region between the light blocking pattern and the light blocking layer, and a diameter of the light blocking pattern is the same as a diameter of the third opening, and a width of the third hole is the same as a separation distance between the third opening and the light blocking layer.

According to some embodiments, a diameter of the light blocking pattern is different from a diameter of the third opening.

According to some embodiments, the light blocking pattern is integrated with the light blocking layer to overlap the third opening, and the third hole does not overlap the third opening.

According to some embodiments, the display device may further comprise a plurality of signal lines on the substrate and arranged so as not to overlap the second hole and the third hole, wherein a center line of a pair of the signal lines adjacent to each other is not parallel to a center line of the third opening.

A display device according to some embodiments may include transmission portions having different opening shapes in a light sensing area. In the display device, the performance of sensing light incident from the side as well as the performance of sensing light incident from the front may be relatively improved.

However, the characteristics of embodiments of the present disclosure are not limited to those described above and various other characteristics are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a schematic perspective view of an electronic device according to some embodiments;

FIG. 2 is a perspective view illustrating a display device included in an electronic device according to some embodiments;

FIG. 3 is a cross-sectional view of the display device of FIG. 2 viewed from the side;

FIG. 4 is a plan view of the display device of FIG. 2;

FIG. 5 is a plan view illustrating the arrangement of holes of a light blocking layer and a pixel electrode in the first display area of the display device according to some embodiments;

FIG. 6 is a plan view illustrating the arrangement of color filters and a pixel electrode in the first display area of the display device according to some embodiments;

FIG. 7 is a cross-sectional view taken along the line X1-X1′ of FIGS. 5 and 6;

FIG. 8 is a plan view showing the arrangement of the emission areas and light transmitting areas in the second display area of the display device according to some embodiments;

FIG. 9 is a cross-sectional view taken along the line X2-X2′ of FIG. 8;

FIG. 10 is a diagram illustrating the relative arrangement of emission areas, a light transmitting area, and signal lines in the second display area of FIG. 8;

FIG. 11 is a plan view showing the second light transmitting area of the display device according to some embodiments;

FIG. 12 is a cross-sectional view showing the second light transmitting area of FIG. 11;

FIGS. 13 and 14 are schematic cross-sectional views of a second light transmitting area of a display device according to some embodiments;

FIGS. 15 to 17 are plan views showing a second light transmitting area of a display device according to some embodiments;

FIG. 18 is a plan view showing a first light transmitting area and a second light transmitting area of a display device according to some embodiments;

FIG. 19 is a plan view showing a second light transmitting area of a display device according to some embodiments;

FIG. 20 is a cross-sectional view showing the second light transmitting area of FIG. 19;

FIG. 21 is a cross-sectional view showing a second light transmitting area of a display device according to some embodiments;

FIG. 22 is a cross-sectional view showing a second light transmitting area of a display device according to some embodiments;

FIGS. 23 to 25 are plan views showing the arrangement of light transmitting areas in a second display area of a display device according to some embodiments; and

FIGS. 26 and 27 are cross-sectional views of a display device according to some embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in more detail with reference to the accompanying drawings.

Hereinafter, aspects of some embodiments will be described in more detail with reference to the accompanying drawings.

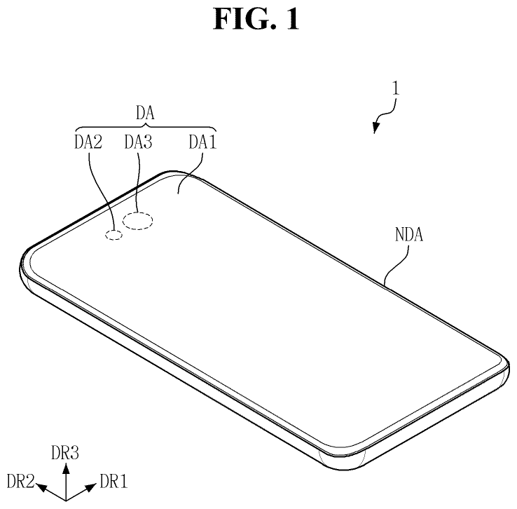

FIG. 1 is a schematic perspective view of an electronic device according to some embodiments.

Referring to FIG. 1, an electronic device 1 displays moving images (e.g., video images) or still images (e.g., static images). The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

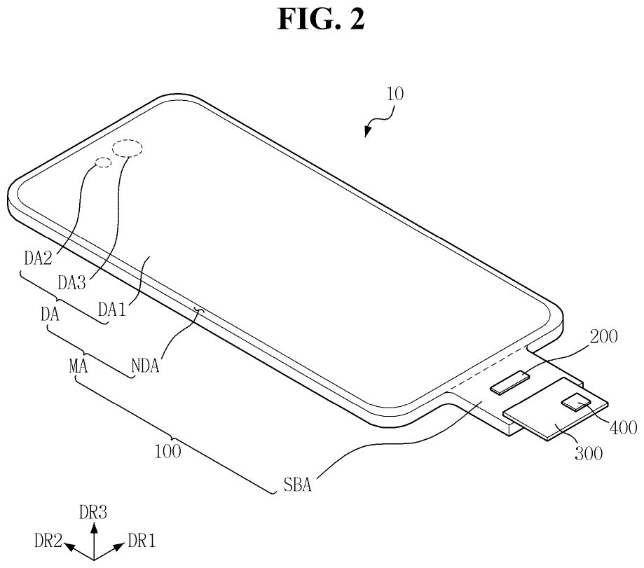

The electronic device 1 may include a display device 10 in FIG. 2 providing a display screen. Examples of the display device may include an inorganic light emitting diode display device, an organic light emitting display device, a quantum dot light emitting display device, a plasma display device and a field emission display device. In the following description, a case where an organic light emitting diode display device is applied as a display device will be described, but embodiments according to the present disclosure are not limited thereto, and other display devices may be applied within the spirit and scope of embodiments according to the present disclosure.

The shape of the electronic device 1 may be variously modified. For example, the electronic device 1 may have a shape such as a rectangular shape elongated in a horizontal direction, a rectangular shape elongated in a vertical direction, a square shape, a quadrilateral shape with rounded corners (vertices), other polygonal shapes and a circular shape. The shape of a display area DA of the electronic device 1 may also be similar to the overall shape of the electronic device 1. FIG. 1 illustrates the electronic device 1 having a rectangular shape elongated in a second direction DR2.

The electronic device 1 may include the display area DA and a non-display area NDA surrounding (e.g., in a periphery or outside a footprint of) the display area DA. The display area DA is an area where images can be displayed, and the non-display area NDA is an area where images are not displayed. The display area DA may also be referred to as an active region, and the non-display area NDA may also be referred to as a non-active region. The display area DA may occupy the center of the electronic device 1.

The display area DA may include a first display area DA1, a second display area DA2, and a third display area DA3. The second display area DA2 and the third display area DA3 are areas in which components for adding various functions to the electronic device 1 are located, and the second display area DA2 and the third display area DA3 may correspond to a component area.

FIG. 2 is a perspective view illustrating a display device included in an electronic device according to some embodiments.

Referring to FIG. 2, the electronic device 1 according to some embodiments may include the display device 10. The display device 10 may display images displayed by the electronic device 1. The display device 10 may have a planar shape similar to the shape of the electronic device 1. For example, the display device 10 may have a shape similar to a rectangular shape having a short side in a first direction DR1 and a long side in the second direction DR2. The edge where the short side in the first direction DR1 and the long side in the second direction DR2 meet may be rounded to have a curvature, but embodiments are not limited thereto and may be formed at a right angle. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA.

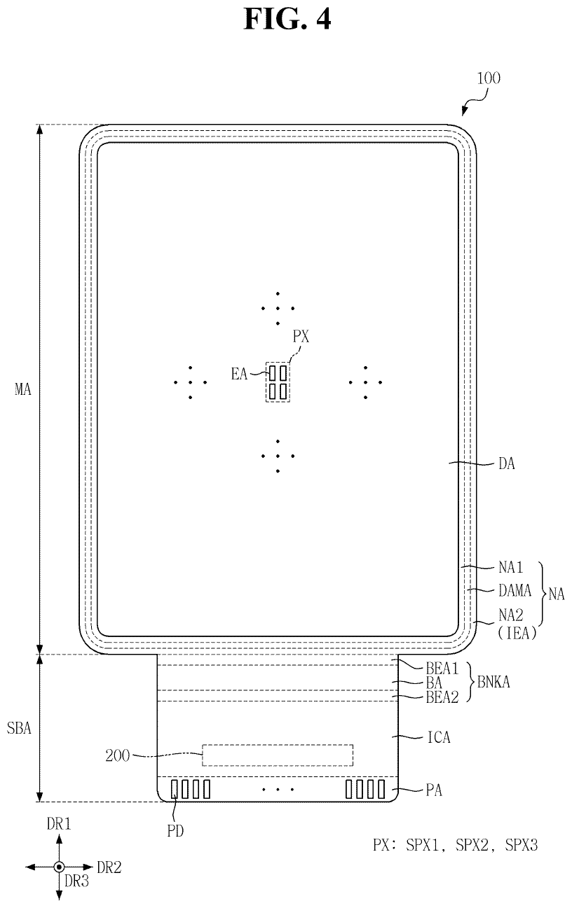

The main region MA may include the display area DA including pixels PX (see FIG. 4) displaying an image and the non-display area NDA arranged around the display area DA. The display area DA may be located in the center of the main region MA, and the non-display area NDA may surround the display area DA. The display area DA may include the first display area DA1, the second display area DA2, and the third display area DA3. The display area DA may emit light from a plurality of emission areas or a plurality of opening areas. For example, the display panel 100 may include a pixel circuit including switching elements, a pixel defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but embodiments are not limited thereto.

The non-display area NDA may be an area outside (e.g., in a periphery or outside a footprint of) the display area DA. The non-display area NDA may be defined as an edge area of the main region MA of the display panel 100. The non-display area NDA may include a gate driver that supplies gate signals to the gate lines, and fan-out lines that connect the display driver 200 to the display area DA.

The sub-region SBA may be a region extending from one side of the main region MA. The sub-region SBA may include a flexible material which can be bent, folded or rolled. For example, when the sub-region SBA is bent, the sub-region SBA may overlap the main region MA in a thickness direction (third direction DR3). The sub-region SBA may include the display driver 200 and a pad portion connected to the circuit board 300. According to some embodiments, the sub-region SBA may be omitted, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be located in the sub-region SBA, and may overlap the main region MA in the thickness direction by bending of the sub-region SBA. For another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a frequency (e.g., a set or predetermined frequency). The touch driver 400 may calculate whether an input is made and input coordinates based on an amount of change in capacitance between the plurality of touch electrodes. The touch driver 400 may be formed as an integrated circuit (IC).

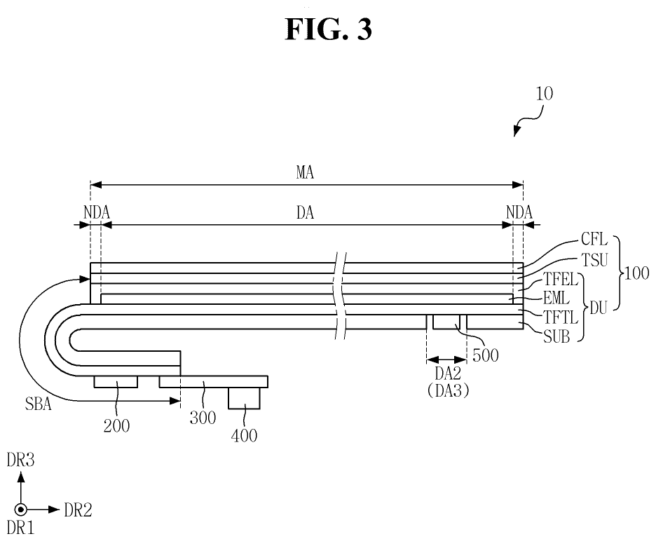

FIG. 3 is a cross-sectional view of the display device of FIG. 2 viewed from the side. FIG. 3 illustrates the sub-region SBA of the display panel 100 in the display device 10 of FIG. 2 in a folded state.

Referring to FIG. 3, the display panel 100 may include a display layer DU, a touch sensing layer TSU, and a color filter layer CFL. The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but is not limited thereto. According to some embodiments, the substrate SUB may include a glass material or a metal material.

The thin film transistor layer TFTL may be located on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The thin film transistor layer TFTL may be located in the display area DA, the non-display area NDA, and the sub-region SBA. Thin film transistors, gate lines, data lines, and power lines of each of the pixels of the thin film transistor layer TFTL may be located in the display area DA. Gate control lines and fan-out lines of the thin film transistor layer TFTL may be located in the non-display area NDA. The lead lines of the thin film transistor layer TFTL may be located in the sub-region SBA.

The light emitting element layer EML may be located on the thin film transistor layer TFTL. The light emitting element layer EML may include a plurality of light emitting elements each including a first electrode, a second electrode, and a light emitting layer to emit light, and a pixel defining layer defining pixels. The plurality of light emitting elements of the light emitting element layer EML may be located in the display area DA.

According to some embodiments, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives the cathode voltage, holes and electrons may be transferred to the organic light emitting layer through the hole transporting layer and the electron transporting layer, respectively and may be combined with each other to emit light in the organic light emitting layer.

According to some embodiments, the light emitting elements may include a quantum dot light emitting diode including a quantum dot light emitting layer, an inorganic light emitting diode including an inorganic semiconductor, or a micro light emitting diode.

The encapsulation layer TFEL may cover the top surface and the side surface of the light emitting element layer EML, and may protect the light emitting element layer EML. The encapsulation layer TFEL may include at least one inorganic layer and at least one organic layer for encapsulating the light emitting element layer EML.

The touch sensing layer TSU may be located on the encapsulation layer TFEL. The touch sensing layer TSU may include a plurality of touch electrodes for sensing a user's touch in a capacitive manner, and touch lines connecting the plurality of touch electrodes to the touch driver 400. For example, the touch sensing layer TSU may sense the user's touch by using a mutual capacitance method or a self-capacitance method.

According to some embodiments, the touch sensing layer TSU may be located on a separate substrate located on the display layer DU. In this case, the substrate supporting the touch sensing layer TSU may be a base member that encapsulates the display layer DU.

The plurality of touch electrodes of the touch sensing layer TSU may be located in a touch sensor area overlapping the display area DA. The touch lines of the touch sensing layer TSU may be located in a touch peripheral area that overlaps the non-display area NDA.

The color filter layer CFL may be located on the touch sensing layer TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent or reduce color distortion caused by reflection of the external light.

Because the color filter layer CFL is directly located on the touch sensing layer TSU, the display device 10 may not require a separate substrate for the color filter layer CFL. Accordingly, the thickness of the display device 10 may be relatively small.

According to some embodiments, the display device 10 may further include an optical device 500. The optical device 500 may be located in the second display area DA2 or the third display area DA3. The optical device 500 may emit or receive light in infrared, ultraviolet, and visible light bands. For example, the optical device 500 may be an optical sensor that detects light incident on the display device 10 such as a proximity sensor, an illuminance sensor, and a camera sensor or an image sensor. In the display device 10, light transmitting areas where the optical device 500 senses incident light may be located in the second display area DA2 and/or the third display area DA3.

FIG. 4 is a plan view of the display device of FIG. 2. FIG. 4 shows the display device 10 in an unbent and unfolded state.

Referring to FIG. 4, the display device 10 may include the main region MA and the sub-region SBA. The main region MA may include the display area DA and the non-display area NA, and the sub-region SBA may include a bank area BNKA, a driving circuit mounting area ICA, and a pad area PA.

The display area DA may be an area where a plurality of pixels PX are located. The pixels PX and wires (or some of the wires) connected to the pixels PX may be located in the display area DA.

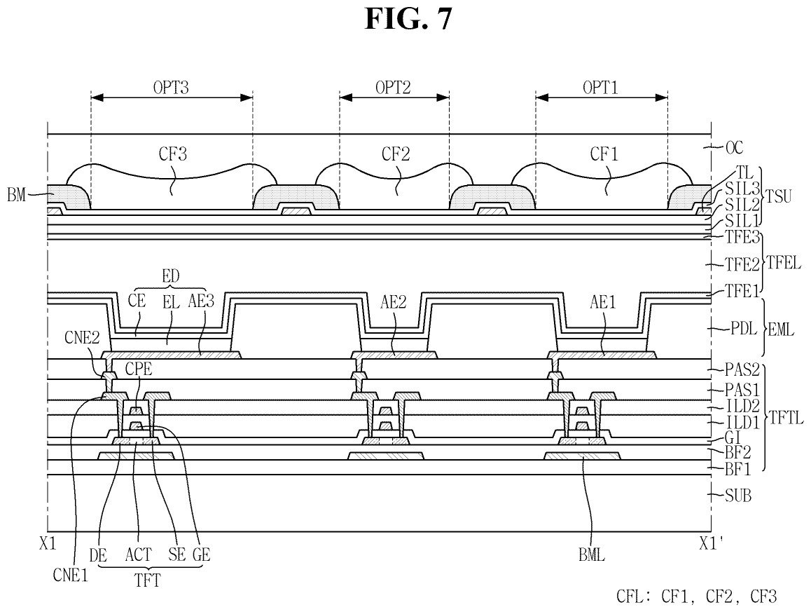

The pixels PX may be provided in the thin film transistor layer TFTL and the light emitting element layer EML of the display device 10. For example, each pixel PX may include a pixel circuit including circuit elements located in the thin film transistor layer TFTL and a light emitting element (e.g., a light emitting element ED of FIG. 7) located in the light emitting element layer EML.

The pixels PX may include at least two color emission areas EA that emit light of different colors. For example, the pixels PX may include a first color emission area emitting light of a first color (e.g., red light), a second color emission area emitting light of a second color (e.g., green light), and a third color emission area emitting light of a third color (e.g., blue light).

At least one first color emission area, at least one second color emission area, and at least one third color emission area adjacent to each other may constitute one unit pixel PX. For example, one first color emission area, two second color emission areas, and one third color emission area adjacent to each other may constitute one unit pixel PX. Each unit pixel PX may emit light of various colors, including white light, by color mixing of light emitted from the emission areas constituting the unit pixel PX. According to some embodiments, the first color emission area and the third color emission area may be arranged alternately in the first direction DR1 and/or the second direction DR2, and the second color emission areas may be arranged continuously and/or sequentially in the first direction DR1. The type, shape, and/or arrangement structure of the emission areas may be variously changed depending on embodiments. Further, the type, number, ratio, and/or arrangement structure of the emission areas constituting each unit pixel PX may also be variously changed depending on embodiments.

The encapsulation layer TFEL may be located on the pixels PX. For example, the encapsulation layer TFEL may be provided in at least the display area DA to cover the pixels PX, and a part of the encapsulation layer TFEL may extend into the non-display area NA.

A plurality of wires may be provided in the thin film transistor layer TFTL, and may be located in the display area DA and the non-display area NA. In addition, wires may be positioned also in the sub-region SBA. For example, the wires may extend from the sub-region SBA through the non-display area NA to the display area DA.

The non-display area NA may be located around (e.g., in a periphery or outside a footprint of) the display area DA. For example, the non-display area NA may be an edge area of the main region MA positioned outside the display area DA.

The non-display area NA may include a dam area DAMA spaced apart from the display area DA, a first non-display area NA1 between the display area DA and the dam area DAMA, and a second non-display area NA2 outside the dam area DAMA. The dam area DAMA may be an area in which a dam surrounding the display area DA is located. The second non-display area NA2 may include an inorganic encapsulation area IEA (also referred to as a “bonding area”) in which the inorganic encapsulation layers of the encapsulation layer TFEL are bonded to each other.

The sub-region SBA may include the bank area BNKA, the driving circuit mounting area ICA, and the pad area PA sequentially arranged on one side of the main region MA. Wires (or parts of wires), banks, and pads PD may be located in the sub-region SBA. At least some of the wires may extend into the main region MA and be connected to the pixels PX.

The bank area BNKA may be an area in which at least one bank is located. According to some embodiments, the bank area BNKA may overlap the bending area BA. For example, the bank area BNKA may include the bending area BA spaced apart from the main region MA, and a first edge area BEA1 and a second edge area BEA2 positioned on both sides of the bending area BA in the first direction DR1. The bank may be provided in the bending area BA and the peripheral areas thereof (e.g., the first edge area BEA1 and the second edge area BEA2 of the bank area BNKA) to cover wires passing through the bending area BA. The display panel 100 may be bent in the bending area BA such that a part of the sub-region SBA may be positioned behind the main region MA.

The driving circuit mounting area ICA may be an area in which the driver 200 is located. Pads for connecting at least some of the wires to the driver 200 may be located in the driving circuit mounting area ICA. For example, in the driving circuit mounting area ICA, input pads for connecting the driver 200 to the specific pads (e.g., data input pads) of the pad area PA and output pads for connecting the driver 200 to the pixels PX may be located.

According to some embodiments, the driver 200 may not be located on the display device 10. In this case, the display device 10 may not include the driving circuit mounting area ICA, and only wires may be located in an area between the bank area BNKA and the pad area PA.

The pad area PA may be an area where the pads PD for connecting the display device 10 and/or the driver 200 to the circuit board 300 and the like are located. The circuit board 300 may be located or bonded on the pad area PA.

A plurality of pads PD including power pads and signal pads connected to the pixels PX, the driver 200, and/or the embedded circuit may be located in the pad area PA. Power voltages for driving the pixels PX, the driver 200, and/or the embedded circuit or the like may be supplied to the power pads. Driving signals and/or image data for driving the pixels PX, the driver 200, and/or the embedded circuit or the like may be supplied to the signal pads. The type, location, arrangement order, and/or number of the pads PD may be variously changed according to embodiments.

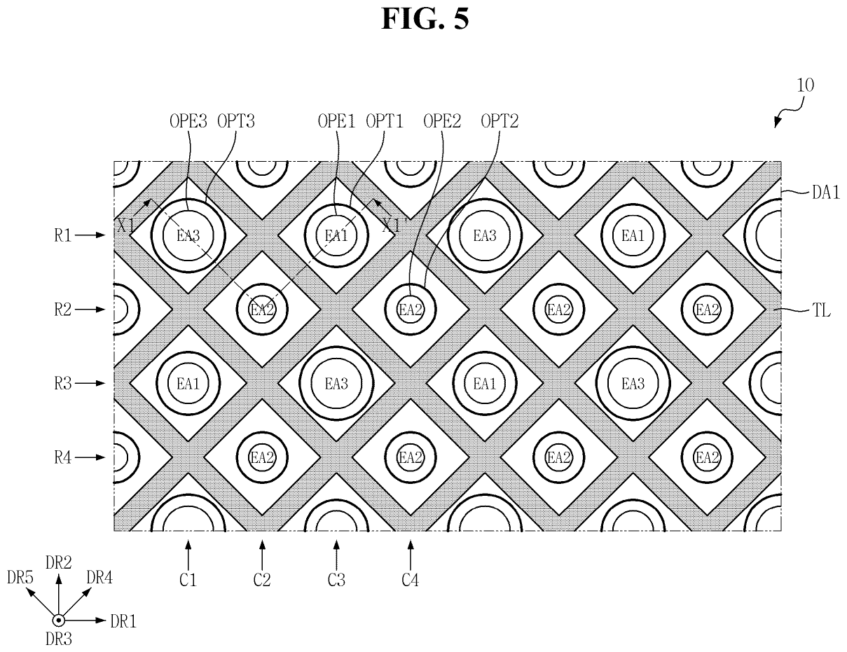

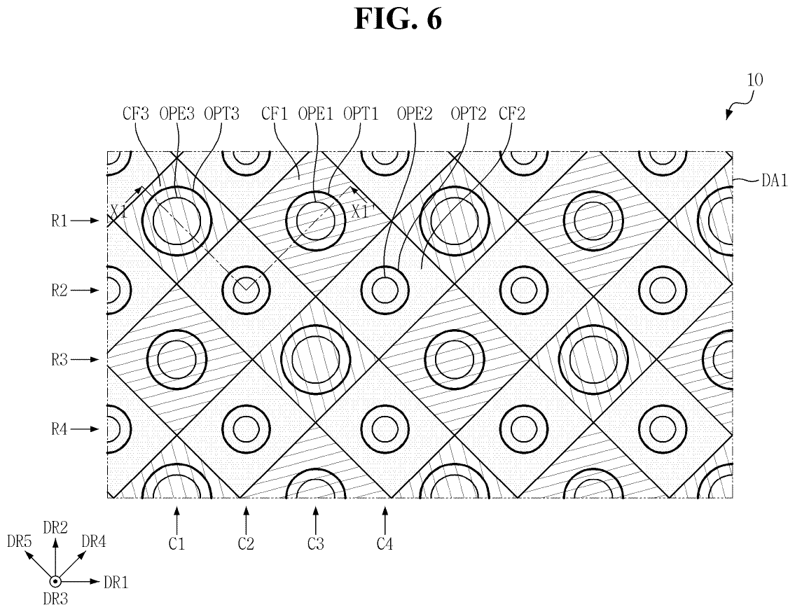

FIG. 5 is a plan view illustrating the arrangement of holes of a light blocking layer and a pixel electrode in the first display area of the display device according to some embodiments. FIG. 6 is a plan view illustrating the arrangement of color filters and a pixel electrode in the first display area of the display device according to some embodiments. FIGS. 5 and 6 show the deposition of first to third holes OPT1, OPT2, and OPT3 of a light blocking layer BM and pixel electrodes AE1, AE2, and AE3 located in the first display area DA1.

Referring to FIGS. 5 and 6, the display device 10 may include a plurality of emission areas EA1, EA2, and EA3 located in the display area DA. The plurality of emission areas EA1, EA2, and EA3 may be arranged in a PenTile™ type, e.g., a diamond PenTile™ type. For example, the plurality of emission areas EA1, EA2, and EA3 may be arranged in a fourth direction DR4 and a fifth direction DR5, which are diagonal directions between the first direction DR1 and the second direction DR2. The first emission area EA1 and the second emission area EA2 may be located adjacent to each other in the fifth direction DR5, and the second emission area EA2 and the third emission area EA3 may be located adjacent to each other in the fourth direction DR4. The first emission area EA1 and the third emission area EA3 may be arranged to be spaced apart from each other in the second direction DR2. In the arrangement of the emission areas EA1, EA2, and EA3, the first emission area EA1 and the third emission area EA3 may be alternately arranged in the first direction DR1 in a first row R1 and a third row R3. In a first column C1 and a third column C3, the first emission area EA1 and the third emission area EA3 may be alternately arranged in the second direction DR2. The second pixel electrode AE2 may be repeatedly arranged in the first direction DR1 in the second row R2 and the fourth row R4, and the second emission area EA2 may be repeatedly arranged in the second direction DR2 in the second column R2 and the fourth column C4.

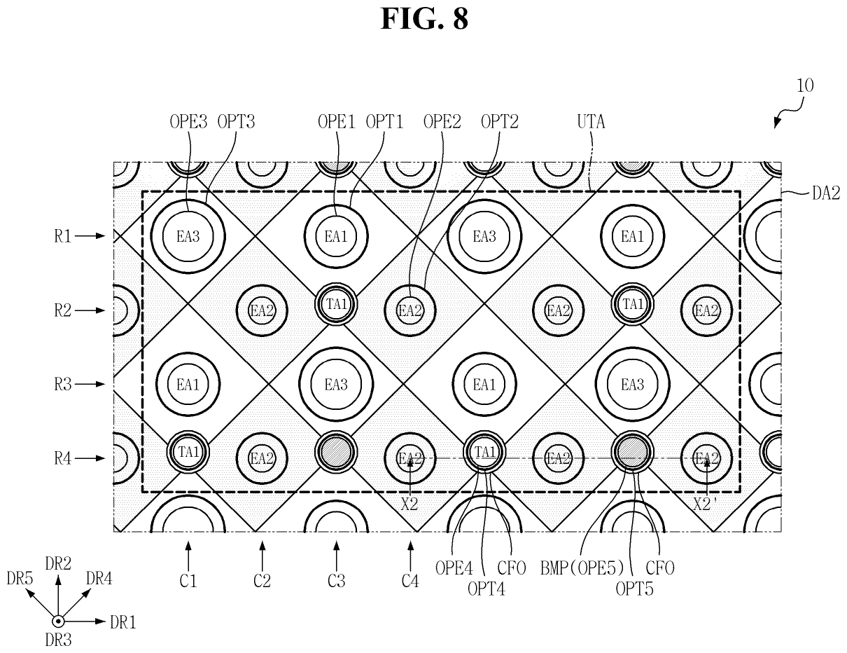

According to some embodiments, in the display device 10, a plurality of pixel electrodes AE1, AE2, and AE3 (see FIG. 8) may be repeatedly arranged in the arrangement of FIG. 4 over the entire display area DA. For example, one pixel PX may include one first pixel electrode AE1, two second pixel electrodes AE2, and one third pixel electrode AE3. The first pixel electrodes AE1, the second pixel electrodes AE2, and the third pixel electrodes AE3 may be arranged similarly to the arrangement of the emission areas EA1, EA2, and EA3. However, embodiments according to the present disclosure are not limited thereto. The number and arrangement of the pixel electrodes AE1, AE2, and AE3 located in the pixel PX may be variously modified.

Each of the pixel electrodes AE1, AE2, and AE3 may be an anode electrode of the light emitting element included in the pixel PX. One pixel PX may include one or more light emitting elements ED (see FIG. 7), and the light emitting elements may be light emitting elements that emit light of different colors. For example, a light emitting element including the first pixel electrode AE1 may emit first light of a red color. A light emitting element including the second pixel electrode AE2 may emit second light of a green color, and a light emitting element including the third pixel electrode AE3 may emit third light of a blue color. However, embodiments according to the present disclosure are not limited thereto. One first pixel electrode AE1, two second pixel electrodes AE2, and one third pixel electrode AE3 may form one pixel PX, and may emit different colors and express a white grayscale. However, embodiments according to the present disclosure are not limited thereto, and the combination of the pixel electrodes AE1, AE2, and AE3 constituting one pixel PX may be modified in various ways depending on the arrangement of the pixel electrodes AE1, AE2, and AE3, the color of light that the pixel electrodes AE1, AE2, and AE3 emit, and the like.

According to some embodiments, the emission areas EA1, EA2, and EA3 of the display device 10 may be areas overlapping the pixel electrodes AE1, AE2, and AE3. Openings OPE1, OPE2, and OPE3 of a pixel defining layer PDL (see FIG. 7) illustrated in FIG. 7, for example, may correspond to the emission areas EA1, EA2, and EA3, and the pixel electrodes AE1, AE2, and AE3 may overlap the openings OPE1, OPE2, and OPE3, respectively. For example, the first pixel electrode AE1 may overlap the first emission area EA1 that emits light of the first color, the second pixel electrode AE2 may overlap the second emission area EA2 that emits light of the second color, and the third pixel electrode AE3 may overlap the third emission area EA3 that emits light of the third color. The first emission area EA1 may be defined by the first opening OPE1 of the pixel defining layer PDL that overlaps the first pixel electrode AE1, the second emission area EA2 may be defined by the second opening OPE2 of the pixel defining layer PDL that overlaps the second pixel electrode AE2, and the third emission area EA3 may be defined by the third opening OPE3 of the pixel defining layer PDL that overlaps the third pixel electrode AE3.

According to some embodiments, the areas or sizes of the first to third emission areas EA1, EA2, and EA3 may be different from each other. Further, the areas or sizes of the first to third pixel electrodes AE1, AE2, and AE3 may be different from each other. According to some embodiments as illustrated in FIG. 5, the area of the third emission area EA3 may be greater than the areas of the first emission area EA1 and the second emission area EA2, and the area of the first emission area EA1 may be greater than the area of the second emission area EA2. The areas of the emission areas EA1, EA2, and EA3 may vary according to the sizes of the openings OPE1, OPE2, and OPE3 formed in the pixel defining layer PDL. Further, the area of the third pixel electrode AE3 may be larger than those of the first pixel electrode AE1 and the second pixel electrode AE2, and the area of the first pixel electrode AE1 may be larger than the area of the second pixel electrode AE2. The luminance of emitted light may vary depending on the area of the emission areas EA1, EA2, and EA3 overlapping the pixel electrodes AE1, AE2, and AE3, and the area of the emission areas EA1, EA2, and EA3 may be adjusted to control the color of the screen displayed on the electronic device 1, or the display device 10. According to some embodiments as illustrated in FIG. 5, the third emission area EA3 having the largest area is illustrated, but is not limited thereto. The size of the pixel electrodes AE1, AE2, and AE3 and the area of the emission areas EA1, EA2, and EA3 may be freely adjusted according to the color of the screen required for the display device 10 and the electronic device 1. In addition, the areas of the pixel electrodes AE1, AE2, and AE3 may be related to light efficiency and the lifespan of the light emitting element ED, and may have a trade-off relation with the reflection by external light. The areas of the pixel electrodes AE1, AE2, and AE3 may be adjusted in consideration of the above factors.

The display device 10 may include the light blocking layer BM and a plurality of color filters CF1, CF2, and CF3 located on the pixel electrodes AE1, AE2, and AE3.

The light blocking layer BM may be arranged over the entire display area DA. The light blocking layer BM may include the plurality of openings OPE1, OPE2, and OPE3, or the plurality of holes OPT1, OPT2, and OPT3 arranged to respectively correspond to the pixel electrodes AE1, AE2, and AE3. The holes OPT1, OPT2, and OPT3 of the light blocking layer BM may be arranged to respectively correspond to the openings OPE1, OPE2, and OPE3 of the pixel defining layer PDL (see FIG. 7). The light blocking layer BM may cover the display area DA except for an area where the holes OPT1, OPT2, and OPT3 are located in the display area DA. The holes of the light blocking layer BM may be regions where lights emitted from the light emitting elements including the pixel electrodes AE1, AE2, and AE3 are emitted.

The plurality of holes OPT1, OPT2, and OPT3 may include a first hole OPT1 overlapping the first emission area EA1 and the first pixel electrode AE1, a second hole OPT2 overlapping the second emission area EA2 and the second pixel electrode AE2, and a third hole OPT3 overlapping the third emission area EA3 and the third pixel electrode AE3. One first hole OPT1, two second holes OPT2, and one third hole OPT3 may be formed in the light blocking layer BM within the area occupied by one pixel PX.

The plurality of holes OPT1, OPT2, and OPT3 may have larger areas in plan view than the emission areas EA1, EA2, and EA3 or the openings OPE1, OPE2, and OPE3, and the pixel electrodes AE1, AE2, and AE3, respectively. For example, the first hole OPT1 may have a larger area in a plan view than the first opening OPE1. The second hole OPT2 and the third hole OPT3 may also have larger areas in plan view than the second opening OPE2 and the third opening OPE3, respectively. Further, each of the holes OPT1, OPT2, and OPT3 of the light blocking layer BM may have a different area in plan view. As described above, the plurality of emission areas EA1, EA2, and EA3 and the openings OPE1, OPE2, and OPE3, and the pixel electrodes AE1, AE2, and AE3 may have different areas, so that the holes OPT1, OPT2, and OPT3 of the light blocking layer BM may also have different sizes. For example, the diameter or size of the third hole OPT3 may be larger than the diameter or size of the first hole OPT1 and the second hole OPT2, and the diameter or size of the first hole OPT1 may be larger than the diameter or size of the second hole OPT2. However, embodiments according to the present disclosure are not limited thereto.

The plurality of color filters CF1, CF2, and CF3 may be arranged to correspond to the emission areas EA1, EA2, and EA3, respectively. For example, the color filters CF1, CF2, and CF3 may be located on the light blocking layer BM, and may be arranged to correspond to the plurality of holes of the light blocking layer BM. The hole of the light blocking layer BM may be formed to overlap the opening of the pixel defining layer PDL (see FIG. 7), and may form a light exit area through which light emitted from the emission area is emitted. The color filters CF1, CF2, and CF3 may have areas larger than those of the holes of the light blocking layer BM, and the color filters CF1, CF2, and CF3 may completely cover the light exit area formed by the holes. Each of the color filters CF1, CF2, and CF3 may completely cover the holes of the light blocking layer BM, and some of them may be directly located on the light blocking layer BM. However, according to some embodiments, the color filters CF1, CF2, and CF3 may be omitted.

The color filters CF1, CF2, and CF3 may include a first color filter CF1, a second color filter CF2, and a third color filter CF3 arranged to correspond to the different emission areas EA1, EA2, and EA3, respectively. The color filters CF1, CF2, and CF3 may include a colorant such as a dye or pigment that absorbs light in a wavelength band different from light in a specific wavelength band, and may be arranged to correspond to the color of light emitted by a light emitting element including the pixel electrodes AE1, AE2, and AE3. For example, the first color filter CF1 may be a red color filter that is arranged to overlap the first emission area EA1 or the first opening OPE1 and transmits only red first light. The second color filter CF2 may be a green color filter that is arranged to overlap the second emission area EA2 or the second opening OPE2 and transmits only green second light, and the third color filter CF3 may be a blue color filter that is arranged to overlap the third emission area EA3 or the third opening OPE3 and transmits only blue third light.

Similarly to the arrangement of the emission areas EA1, EA2, and EA3, the color filters CF1, CF2, and CF3 may be arranged in a PenTile™ type, e.g., a diamond PenTile™ type. For example, the first color filter CF1 and the third color filter CF3 may be alternately arranged in the first direction DR1 and the second direction DR2. The second color filter CF2 and another adjacent second color filter CF2 may be arranged in the first direction DR1 and the second direction DR2, and the second color filter CF2 and the adjacent first color filter CF1 and the adjacent third color filter CF3 may be arranged in the fourth direction DR4 or the fifth direction DR5. The plurality of second color filters CF2 may be repeatedly arranged along the first direction DR1 and the second direction DR2, and the second color filter CF2 and the first color filter CF1, or the second color filter CF2 and the third color filter CF3 may be alternately arranged along the fourth direction DR4 or the fifth direction DR5.

According to some embodiments, the plurality of color filters CF1, CF2, and CF3 may have different areas in plan view. As described above, the areas of the plurality of emission areas EA1, EA2, and EA3 may be different from each other, and accordingly, the sizes of the holes of the light blocking layer BM, and the areas of the color filters CF1, CF2, and CF3 in plan view may also be different from each other. For example, the area of the first color filter CF1, which is a red color filter, may be larger than the areas of the second color filter CF2, which is a green color filter, and the third color filter CF3, which is a blue color filter. Additionally, the area of the third color filter CF3 may be larger than the area of the second color filter CF2.

The color filters CF1, CF2, and CF3 may have a quadrilateral shape, a rectangular shape, or a rhombic shape including sides extending in the fourth direction DR4 and the fifth direction DR5. The first color filter CF1 and the third color filter CF3 may have sides of the same length extending in the fourth direction DR4 and the fifth direction DR5, and may have a quadrilateral shape or a rhombic shape in plan view. The area of the first color filter CF1 in plan view may be larger than the area of the third color filter CF3, and the second color filter CF2 adjacent to the first color filter CF1 and the third color filter CF3 may have sides of different lengths extending in the fourth direction DR4 and the fifth direction DR5 and have a rectangular shape in plan view. In other words, the extending sides of the first color filter CF1 and the third color filter CF3 have the same length and thus may have shapes that are not affected by locations, whereas the extending sides of the second color filter CF2 have different lengths and thus may have different extension directions of the long sides depending on locations. In the case of describing the shape of the second color filters CF2 shown in FIG. 6, for example, the second color filter CF2 located in a second column C2 of a second row R2 may have a shape in which the long side extends in the fourth direction DR5, and the second color filter CF2 located in a fourth column C4 of the second row R2 and may have a shape in which the long side extends in the fifth direction DR4.

However, embodiments according to the present disclosure are not limited thereto. According to some embodiments, the shape of the color filters CF1, CF2, and CF3 in plan view may be a circular shape similar to the shape of the emission areas EA1, EA2, and EA3. The display device 10 according to some embodiments may be designed such that the planar shape and area of the color filters CF1, CF2, and CF3 allow external light of the display device 10 to have a specific color.

According to some embodiments, the planar area ratio of the first color filter CF1 and the second color filter CF2 may be in a range of 1:0.3 to 1:0.7 (or about 1:0.3 to 1:0.7), and the area ratio of the first color filter CF1 and the third color filter CF3 may be in a range of 1:0.4 to 1:1 (or about 1:0.4 to 1:1). For example, the area ratio of the first color filter CF1, the second color filter CF2, and the third color filter CF3 may be 1:0.59:0.52 or 1:0.59:1. However, the area ratio of the color filters CF1, CF2, and CF3 is not limited to the above-described, and the planar areas of the color filters CF1, CF2, and CF3 may be designed differently such that the reflected light in the display device 10 and the electronic device 1 has desired color coordinates.

The display device 10 may include the color filters CF1, CF2, and CF3 located on the display layer DU to reduce the intensity of reflected light caused by external light. Furthermore, the color of the reflected light by the external light may be controlled by adjusting the arrangement, shape, and area of the color filters CF1, CF2, and CF3 in plan view.

A touch electrode TL may be located between the emission areas EA1, EA2, and EA3, or between the holes OPT1, OPT2, and OPT3 of the light blocking layer BM. The touch electrode TL may be arranged to extend in the fourth direction DR4 and the fifth direction DR5, and may be spaced apart from the holes OPT1, OPT2, and OPT3 of the light blocking layer BM. The touch electrode TL may be arranged to overlap the pixel defining layer PDL (see FIG. 7) and the light blocking layer BM. Although the touch electrode TL is briefly illustrated in the drawing, the touch electrode TL may include a touch driving electrode and a sensing electrode.

FIG. 7 is a cross-sectional view taken along the line X1-X1′ of FIGS. 5 and 6. FIG. 7 shows a cross section across the first to third pixel electrodes AE1, AE2, and AE3 in one pixel PX of the first display area DA1.

A cross-sectional structure of the display device 10 will be described with reference to FIG. 7. The display device 10 may include the display layer DU, the touch sensing layer TSU, the light blocking layer BM, the color filter layer CFL, and an overcoat layer OC. The display layer DU may include the substrate SUB, the thin film transistor layer TFTL, the light emitting element layer EML, and the encapsulation layer TFEL. The light blocking layer BM may be located on the touch sensing layer TSU of the display panel 100, and the color filters CF1, CF2, and CF3 of the color filter layer CFL may be located on the light blocking layer BM. The overcoat layer OC may be located on the color filter layer CFL and the light blocking layer BM.

The substrate SUB may be a base substrate or a base member. The substrate SUB may be a flexible substrate which can be bent, folded or rolled. For example, the substrate SUB may include a polymer resin such as polyimide (PI), but is not limited thereto. For another example, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be located on the substrate SUB. The first buffer layer BF1 may include an inorganic layer capable of preventing or reducing penetration of contaminants such as air or moisture. For example, the first buffer layer BF1 may include a plurality of inorganic layers alternately stacked.

The lower metal layer BML may be located on the first buffer layer BF1. For example, the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the lower metal layer BML. The second buffer layer BF2 may include an inorganic layer capable of preventing or reducing penetration of contaminants such as air or moisture. For example, the second buffer layer BF2 may include a plurality of inorganic layers alternately stacked.

The thin film transistor TFT may be located on the second buffer layer BF2, and may constitute a pixel circuit of each of a plurality of pixels. For example, the thin film transistor TFT may be a switching transistor or a driving transistor of the pixel circuit. The thin film transistor TFT may include a semiconductor layer ACT, a source electrode SE, a drain electrode DE, and a gate electrode GE.

The semiconductor layer ACT may be located on the second buffer layer BF2. The semiconductor layer ACT may overlap the lower metal layer BML and the gate electrode GE in the thickness direction, and may be insulated from the gate electrode GE by the gate insulating layer GI. In a part of the semiconductor layer ACT, a material of the semiconductor layer ACT may be made into a conductor to form the source electrode SE and the drain electrode DE.

The gate electrode GE may be located on the gate insulating layer GI. The gate electrode GE may overlap the semiconductor layer ACT with the gate insulating layer GI interposed therebetween.

The gate insulating layer GI may be located on the semiconductor layer ACT. For example, the gate insulating layer GI may cover the semiconductor layer ACT and the second buffer layer BF2 to insulate the gate electrode GE from the semiconductor layer ACT. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and the contact hole of the second interlayer insulating layer ILD2.

The capacitor electrode CPE may be located on the first interlayer insulating layer ILD1. The capacitor electrode CPE may overlap the gate electrode GE in the thickness direction. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be located on the second interlayer insulating layer ILD2. The first connection electrode CNE1 may electrically connect the drain electrode DE of the thin film transistor TFT to the second connection electrode CNE2. The first connection electrode CNE1 may be inserted into a contact hole provided in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be located on the first passivation layer PAS1. The second connection electrode CNE2 may electrically connect the first connection electrode CNE1 to a pixel electrode AE of the light emitting element ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED passes.

The light emitting element layer EML may be located on the thin film transistor layer TFTL. The light emitting element layer EML may include the light emitting element ED and the pixel defining layer PDL. The light emitting element ED may include the pixel electrodes AE1, AE2, and AE3, a light emitting layer EL, and a common electrode CE.

The pixel electrodes AE1, AE2, and AE3 may be located on the second passivation layer PAS2. Each of the different pixel electrodes AE1, AE2, and AE3 may be arranged to overlap one of the different openings of the pixel defining layer PDL. The pixel electrodes AE1, AE2, and AE3 may be electrically connected to the drain electrode DE of the thin film transistor TFT through the first and second connection electrodes CNE1 and CNE2.

The light emitting layer EL may be located on the pixel electrodes AE1, AE2, and AE3. For example, the light emitting layer EL may be an organic light emitting layer made of an organic material, but is not limited thereto. In the case of employing the organic light emitting layer as the light emitting layer EL, the thin film transistor TFT applies a voltage (e.g., a set or predetermined voltage) to the pixel electrodes AE1, AE2, and AE3 of the light emitting element ED, and if the common electrode CE of the light emitting element ED receives a common voltage or a cathode voltage, the holes and electrons can move to the light emitting layer EL through the hole transporting layer and the electron transporting layer and combine to produce light to be emitted by the light emitting layer EL.

According to some embodiments, the light emitting layers EL located on different pixel electrodes AE1, AE2, and AE3 may emit light of different colors. For example, the light emitting layer located on the first pixel electrode AE1 may emit red light of the first color, the light emitting layer located on the second pixel electrode AE2 may emit green light of the second color, and the light emitting layer located on the third pixel electrode AE3 may emit blue light of the third color. However, the present disclosure is not limited thereto. According to some embodiments, the light emitting layer EL may be arranged as one common layer on the different pixel electrodes AE1, AE2, and AE3 and the pixel defining layer PDL, or the light emitting layer EL located on the different pixel electrodes AE1, AE2, and AE3 may emit light of the same color. In this case, the display device 10 may further include a color adjustment layer located on the light emitting elements ED.

The common electrode CE may be arranged on the light emitting layer EL. For example, the common electrode CE may be made in the form of an electrode common to all of the pixels rather than specific to each of the pixels. The common electrode CE may be located on the light emitting layer EL in the first to third pixel electrodes AE1, AE2, and AE3, and may be located on the pixel defining layer PDL in an area other than the first to third pixel electrodes AE1, AE2, and AE3.

The common electrode CE may receive the common voltage or a low potential voltage. When the pixel electrode AE receives a voltage corresponding to a data voltage and the common electrode CE receives the low potential voltage, a potential difference is formed between the pixel electrodes AE1, AE2, and AE3 and the common electrode CE, so that the light emitting layer EL may emit light.

The pixel defining layer PDL may include the plurality of openings OPE1, OPE2, and OPE3, and may be located on a part of the second passivation layer PAS2 and the pixel electrodes AE1, AE2, and AE3. The openings OPE1, OPE2, and OPE3 of the pixel defining layer PDL may expose a part of the pixel electrodes AE1, AE2, and AE3, respectively. As described above, each of the openings OPE1, OPE2, and OPE3 of the pixel defining layer PDL may define the first to third emission areas EA1, EA2, and EA3, and the areas or sizes of the openings OPE1, OPE2, and OPE3 may be different. The pixel defining layer PDL may separate and insulate the pixel electrodes AE1, AE2, and AE3 of each of the plurality of light emitting elements ED. The pixel defining layer PDL may include a light absorbing material to prevent or reduce light reflection. For example, the pixel defining layer PDL may include a polyimide (PI)-based binder and a pigment in which red, green, and blue colors are mixed. Alternatively, the pixel defining layer PDL may include a cardo-based binder resin and a mixture of a lactam black pigment and a blue pigment. Alternatively, the pixel defining layer PDL may include carbon black.

The encapsulation layer TFEL may be located on the common electrode CE to cover the plurality of light emitting elements ED. The encapsulation layer TFEL may include at least one inorganic layer to prevent or reduce instances of contaminants such as oxygen or moisture penetrating into the light emitting element layer EML. The encapsulation layer TFEL may include at least one organic layer to protect the light emitting element layer EML from foreign matters such as dust.

According to some embodiments, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 located between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include acrylic resin, epoxy resin, polyimide, polyethylene and the like. For example, the second encapsulation layer TFE2 may include an acrylic resin, for example, polymethyl methacrylate, polyacrylic acid, or the like. The second encapsulation layer TFE2 may be formed by curing a monomer or applying a polymer.

The touch sensing layer TSU may be located on the encapsulation layer TFEL. The touch sensing layer TSU may include a first touch insulating layer SIL1, a second touch insulating layer SIL2, the touch electrode TL, and a third touch insulating layer SIL3.

The first touch insulating layer SIL1 may be located on the encapsulation layer TFEL. The first touch insulating layer SIL1 may have an insulating and optical function. The first touch insulating layer SIL1 may include at least one inorganic layer. Optionally, the first touch insulating layer SIL1 may be omitted.

The second touch insulating layer SIL2 may cover the first touch insulating layer SIL1. According to some embodiments, a touch electrode of another layer may be further located on the first touch insulating layer SIL1, and the second touch insulating layer SIL2 may cover the touch electrode TL. The second touch insulating layer SIL2 may have an insulating and optical function. For example, the second touch insulating layer SIL2 may be an inorganic layer containing at least one of a silicon nitride layer, a silicon oxynitride layer, a silicon oxide layer, a titanium oxide layer, or an aluminum oxide layer.

A part of the touch electrode TL may be located on the second touch insulating layer SIL2. The touch electrode TL may not overlap the first to third pixel electrodes AE1, AE2, and AE3. The touch electrode TL may be formed of a single layer containing molybdenum (Mo), titanium (Ti), copper (Cu), aluminum (AI), or indium tin oxide (ITO), or may be formed to have a stacked structure (Ti/Al/Ti) of aluminum and titanium, a stacked structure (ITO/AI/ITO) of aluminum and ITO, an Ag—Pd—Cu (APC) alloy, or a stacked structure (ITO/APC/ITO) of APC alloy and ITO.

The touch electrode TL of the touch sensing layer TSU may have a constant line width and may be arranged to overlap the light blocking layer BM, which will be described later. The light blocking layer BM may have a width sufficient to completely cover the touch electrode TL, and a gap between an edge of the light blocking layer BM and the touch electrode TL may be defined. According to some embodiments, the line width of the touch electrode TL may be in a range of 4 μm to 6 μm, and the gap between the touch electrode TL and the edge of the light blocking layer BM may be in a range of 5 μm to 7 μm. The touch electrode TL may be arranged such that the center thereof is almost parallel to the center of the light blocking layer BM, and the gap from both sides of the touch electrode TL to the edge of the light blocking layer BM may be constant (or approximately constant).

The third touch insulating layer SIL3 may cover the touch electrode TL and the second touch insulating layer SIL2. The third touch insulating layer SIL3 may have an insulating and optical function. The third touch insulating layer SIL3 may be made of the material illustrated and described in association with the second touch insulating layer SIL2.

The light blocking layer BM may be located on the third touch insulating layer SIL3 of the touch sensing layer TSU. The light blocking layer BM may be arranged to cover the conductive line of the touch electrode TL, while including the plurality of holes OPT1, OPT2, and OPT3 that overlap the pixel electrodes AE1, AE2, and AE3. For example, the first hole OPT1 may be arranged to overlap the first pixel electrode AE1. The second hole OPT2 may be arranged to overlap the second pixel electrode AE2, and the third hole OPT3 may be arranged to overlap the third pixel electrode AE3. The areas or sizes of the holes OPT1, OPT2, and OPT3 may be larger than the areas or sizes of the pixel electrodes AE1, AE2, and AE3. In addition, the holes OPT1, OPT2, and OPT3 are formed to be larger in area or size than the openings OPE1, OPE2, and OPE3 of the pixel defining layer PDL, so that the light emitted from the light emitting element ED may be visually recognized by the user not only from the front but also from the side of the display device 10.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, or aniline black, but embodiments are not limited thereto. The light blocking layer BM may prevent or reduce visible light infiltration and color mixture between the holes OPT1, OPT2, and OPT3, which may lead to the improvement of color reproducibility of the display device 10. According to some embodiments, the light blocking layer BM may have a thickness of 1 μm to 3 μm, or 1.5 μm (or approximately 1.5 μm).

The color filters CF1, CF2, and CF3 of the color filter layer CFL may be located on the light blocking layer BM. The different color filters CF1, CF2, and CF3 may be arranged to correspond to the different pixel electrodes AE1, AE2, and AE3 and the holes OPT1, OPT2, and OPT3 of the light blocking layer BM, respectively. For example, the first color filter CF1 may be arranged to correspond to the first pixel electrode AE1, the second color filter CF2 may be arranged to correspond to the second pixel electrode AE2, and the third color filter CF3 may be arranged to correspond to the third pixel electrode AE3. In the first pixel PX1, the first color filter CF1 may be located in the first hole OPT1 of the light blocking layer BM, the second color filter CF2 may be located in the second hole OPT2 of the light blocking layer BM, and the third color filter CF3 may be located in the third hole OPT3 of the light blocking layer BM. Each of the color filters CF1, CF2, and CF3 may be formed to have a larger area in plan view than the holes OPT1, OPT2, and OPT3 of the light blocking layer BM, and some may be located directly on the light blocking layer BM.

The areas of the plurality of color filters CF1, CF2, and CF3 may vary depending on the sizes of the holes OPT1, OPT2, and OPT3 of the light blocking layer BM. For example, the first color filter CF1 may have a larger area in plan view than the second color filter CF2, but may have a smaller area in plan view than the third color filter CF3.

The overcoat layer OC may be located on the light blocking layer BM and the color filter layer CFL. The overcoat layer OC may be arranged over the entire display area DA to flatten the top surface of the display device 10. The overcoat layer OC may be a colorless light transmissive layer that does not have a color in a visible light band. For example, the overcoat layer OC may include a colorless light transmissive organic material such as an acrylic resin.

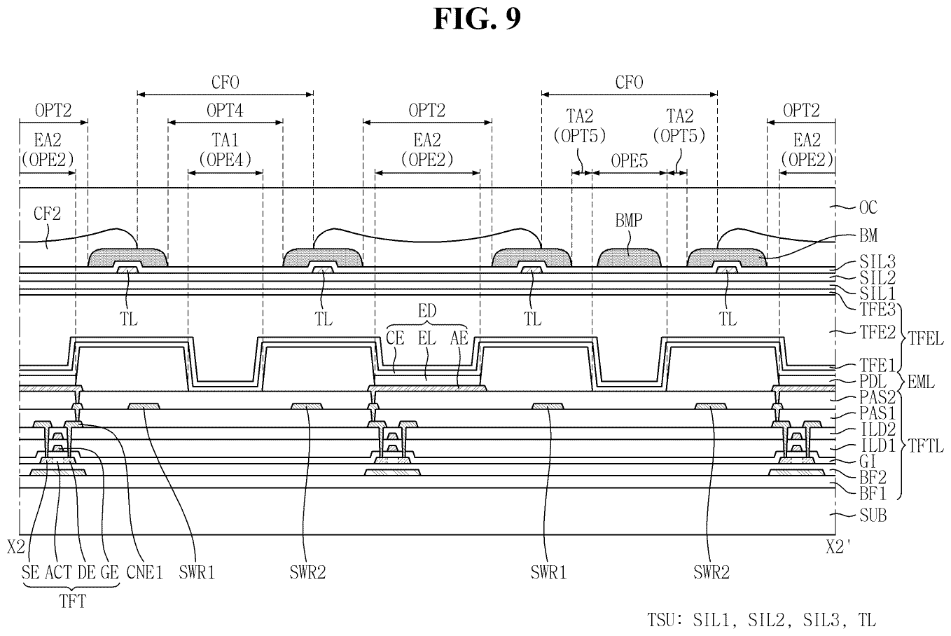

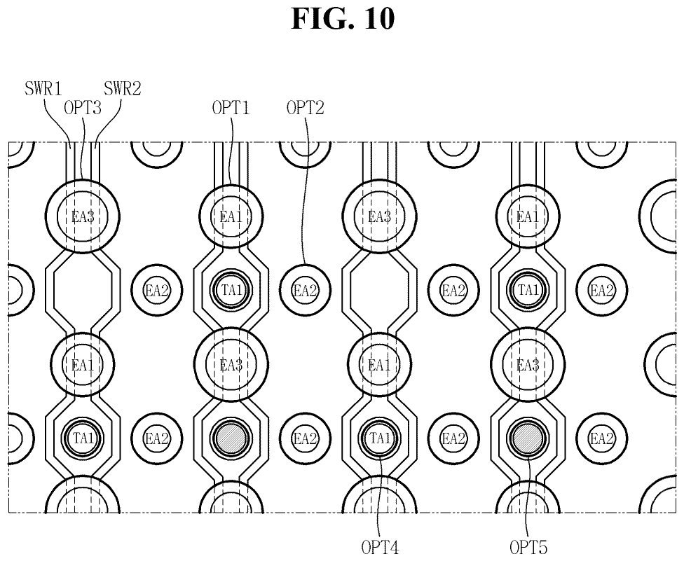

FIG. 8 is a plan view showing the arrangement of the emission areas and light transmitting areas in the second display area of the display device according to some embodiments. FIG. 9 is a cross-sectional view taken along the line X2-X2′ of FIG. 8. FIG. 10 is a diagram illustrating the relative arrangement of emission areas, a light transmitting area, and signal lines in the second display area of FIG. 8.

FIGS. 8 to 10 illustrate a plurality of light transmitting areas TA1 and TA2 in the second display area DA2, for example, but the description thereof may be equally applied to the third display area DA3.

Referring to FIGS. 8 to 10, the display device 10 may include the plurality of light transmitting areas TA1 and TA2, and the plurality of emission areas EA1, EA2, and EA3 located in the second display area DA2 and the third display area DA3 of the display area DA. The touch electrodes TL, the color filters CF1, CF2, and CF3, and the light blocking layer BM may also be located in the second display area DA2. Further, according to some embodiments, the pixel electrodes AE1, AE2, and AE3 may be located in the second display area DA2 and the third display area DA3 to correspond to the emission areas EA1, EA2, and EA3, and light may be emitted from the light emitting elements. A description thereof is the same as described above.

The plurality of light emitting areas TA1 and TA2 may be located between adjacent emission areas EA1, EA2, and EA3. For example, the plurality of light transmitting areas TA1 and TA2 may be located between two emission areas adjacent in the first direction DR1, and between two emission areas EA1, EA2, and EA3 adjacent in the second direction DR2. The plurality of emission areas TA1 and TA2 may be adjacent to the second emission area EA2 in the first direction DR1, and may be adjacent to the first emission area EA1 and the third emission area EA3 in the second direction DR2. The plurality of light transmitting areas TA1 and TA2 may be located in the first column C1 and the third column C3 in the second row R2 and the fourth row R4. On the other hand, the light transmitting areas TA1 and TA2 may not be located in the first row R1 and the third row R3. Further, as shown in the drawing, the light transmitting areas TA1 and TA2 may not be located in the first column C1 of the second row R2, but the present disclosure is not limited thereto.

According to some embodiments, in the second display area DA2 of the display device 10, the number of the first light transmitting areas TA1 and the number of the second light transmitting areas TA2 per unit area UTA may be different. For example, in the second display area DA2, the unit area UTA corresponding to four pixel areas may be defined. According to some embodiments in which one first emission area EA1, two second emission areas EA2, and one third emission area EA3 are included to correspond to one pixel area, four first emission areas EA1, eight second emission areas EA2, and four third emission areas EA3 may be located in the unit area UTA of the second display area DA2.

The arrangement of the first light transmitting area TA1 and the second light transmitting area TA2 may be similar or substantially similar to the arrangement of the second light emitting area EA2. That is, a space for deposition of eight light transmitting areas TA1 and TA2 may exist in one unit area UTA. In the display device 10, the number of the first to third holes OPT1, OPT2, and OPT3 corresponding to the emission areas EA1, EA2, and EA3 in the second display area DA2 may be larger than the number of the fourth hole OPT4 and the fifth hole OPT5.

In the display device 10, eight light transmitting areas TA1 and TA2 may not be necessarily formed in the unit area UTA of the second display area DA2, and only some of them may be formed. For example, in the display device 10, four first light transmitting areas TA1 and two second light transmitting areas TA2 may be formed in the unit area UTA of the second display area DA2. That is, the display device 10 may have arrangement of ‘4/8 first light transmitting area TA1+2/8 second light transmitting area TA2’. In the display device 10, the number of the first light transmitting areas TA1 may be larger than the number of the second light transmitting areas TA2 in the unit area UTA. Further, the number and arrangement of spaces where the light transmitting areas TA1 and TA2 may be formed in the unit area UTA may be the same as the number and arrangement of the second holes OPT2 corresponding to the second emission areas EA2, but each of the number of the first light transmitting areas TA1 and the number of the second light transmitting areas TA2 in the second display area DA2 may be smaller than the number of the second holes OPT2. However, the present disclosure is not limited thereto, and the arrangement and number of the light transmitting areas TA1 and TA2 may be variously modified.

The plurality of light transmitting areas TA1 and TA2 may be defined by the fourth hole OPT4 and the fifth hole OPT5 of the light blocking layer BM. For example, the first light transmitting area TA1 may be formed in the fourth hole OPT4 of the light blocking layer BM that overlaps a fourth opening OPE4 of the pixel defining layer PDL. The plurality of color filters CF1, CF2, and CF3 may form a color filter opening CFO that is not located on the first light transmitting area TA1 and overlaps the fourth hole OPT4. In the thin film transistor layer TFTL, wires and electrodes may not be located at a portion overlapping the first light transmitting area TA1 and the fourth opening OPE4, and light incident from the outside of the display device 10 may be transmitted to the rear surface of the substrate SUB in the first light transmitting area TA1. The optical device 500 located in the second display area DA2 may sense light incident from the outside through the first light transmitting area TA1.

The second light transmitting area TA2 may be defined by the fifth hole OPT5 of the light blocking layer BM. According to some embodiments, the light blocking layer BM may include a light blocking pattern BMP arranged to overlap a fifth opening OPE5 of the pixel defining layer PDL, and the fifth hole OPT5 may be arranged to surround the light blocking pattern BMP. The second light transmitting area TA2 may also be formed to surround the light blocking pattern BMP. The plurality of color filters CF1, CF2, and CF3 may form the color filter opening CFO that is not located on the second light transmitting area TA1 and the light blocking pattern BMP and overlaps the fifth hole OPT5. In the thin film transistor layer TFTL, wires and electrodes may not be located at a portion overlapping the second light transmitting area TA2 and the fifth opening OPE5, and the light incident from the outside of the display device 10 may be transmitted to the rear surface of the substrate SUB in the second light transmitting area TA2. The optical device 500 located in the second display area DA2 may also sense the light incident from the outside through the second light transmitting area TA2.

The pixel defining layer PDL may include the fourth opening OPE4 and the fifth opening OPE5 located in the second display area DA2. The fourth opening OPE4 may overlap the fourth hole OPT4 of the light blocking layer BM. The fifth opening OPE5 may overlap the light blocking pattern BMP surrounded by the fifth hole OPT5 of the light blocking layer BM. The sizes or diameters of the fourth opening OPE4 and the fifth opening OPE5 may be smaller than the sizes or diameters of the first to third openings OPE1, OPE2, and OPE3, and the sizes or diameters of the light transmitting areas TA1 and TA2 may be smaller than the sizes or areas of the first to third holes OPT1, OPT2, and OPT3. Although the pixel defining layer PDL may include a light absorbing material, the pixel defining layer PDL is not located in the first light transmitting area TA1, so that light may be smoothly incident on the optical device 500. Further, the fifth opening OPE5 of the pixel defining layer PDL is located at the lower portion of the second light transmitting area TA2, so that the light incident from the side may be incident on the optical device 500. The common electrode CE of the light emitting element ED, and the encapsulation layer TFEL may be located at the fourth opening OPE4 and the fifth opening OPE5 of the pixel defining layer PDL.

As shown in FIG. 10, the display device 10 may include a plurality of signal lines SWR1 and SWR2 extending in the second direction DR2, and they may be arranged across the plurality of emission areas EA1, EA2, and EA3. The signal lines SWR1 and SWR2 may be located on the first passivation layer PAS1, and may overlap the pixel electrodes AE1, AE2, and AE3. The pixel electrodes AE1, AE2, and AE3 may be located in the emission areas EA1, EA2, and EA3, and the light incident from the outside may be reflected from the pixel electrodes AE1, AE2, and AE3 without reaching the substrate SUB. Further, the light emitting layer EL is located on the pixel electrodes AE1, AE2, and AE3 to emit light, so that the signal lines SWR1 and SWR2 may be located in the emission areas EA1, EA2, and EA3.

However, the first light transmitting area TA1 overlaps the fourth opening OPE4 of the pixel defining layer PDL and transmits light, so that the signal lines SWR1 and SWR2 may not overlap the first light transmitting area TA1 and the fourth opening OPE4 of the pixel defining layer PDL. A pair of the first signal line SWR1 and the second signal line SWR2 may extend side by side in the second direction DR2 and then may be bent around the first light transmitting area TA1 so as not to overlap it.

Also in the case of the second light transmitting area TA2, light transmits through the fifth opening OPE5 of the pixel defining layer PDL, so that the signal lines SWR1 and SWR2 may not overlap the fifth light transmitting area TA2, the light blocking pattern BMP, and the fifth opening OPE5 of the pixel defining layer PDL. A pair of the first signal line SWR1 and the second signal line SWR2 may extend side by side in the second direction DR2 and then may be bent around the second light transmitting area TA2 so as not to overlap it. The first signal line SWR1 and the second signal line SWR2 may be arranged to overlap the pixel defining layer PDL around the fourth opening OPE4 and the fifth opening OPE5 of the pixel defining layer PDL, respectively.

However, the present disclosure is not limited thereto. A region where light is not incident from both the front surface and the side surface of the display device 10 may be formed at a portion of the fifth opening OPE5 of the pixel defining layer PDL that overlaps the light blocking pattern BMP, and the signal lines SWR1 and SWR2 may be located in the corresponding region. In this case, the signal lines SWR1 and SWR2 may overlap the light blocking pattern BMP.

The touch electrode TL may also be located in the second display area DA2. The touch electrode TL may be arranged to extend in the fourth direction DR4 and the fifth direction DR5, and may extend while bypassing the light transmitting areas TA1 and TA2. A part of the touch electrode TL may be bent near the light transmitting areas TA1 and TA2. The touch electrode TL may be arranged so as not to overlap the fourth opening OPE4 and the fifth opening OPE5 of the pixel defining layer PDL. As described above, the touch electrode TL may be arranged to bypass the light transmitting areas TA1 and TA2 in plan view, and may be arranged to be spaced apart from the fourth opening OPE4 and the fifth opening OPE5 in cross-sectional view.

The light blocking layer BM may include the fourth hole OPT4 overlapping the fourth opening OPE4, the light blocking pattern BMP overlapping the fifth opening OPE5, and the fifth hole OPT5 arranged around the light blocking pattern BMP. The size or area of the fourth hole OPT4 may be larger than the size of area of the fourth opening OPE4. Because the fourth hole OPT4 of the light blocking layer BM is formed to be larger than the fourth opening OPE4 of the pixel defining layer PDL, even if lights entering from the outside are incident from the side as well as the front of the display device 10, the optical device 500 may sense the lights. The fifth hole OPT5 may have a width (e.g., a set or predetermined width) and may be located at the periphery of the light blocking pattern BMP, for example, may be arranged to surround the periphery thereof. Because the fifth hole OPT5 is located at the periphery of the light blocking pattern BMP that overlaps the fifth opening OPE5, lights incident from the side of the display device 10 may transmit through the fifth hole OPT5 and the fifth opening OPE5 and be incident on the optical device 500. The size or area of the fifth hole OPT5 may be larger than the size or area of the fifth opening OPE5.

The color filters CF1, CF2, and CF3 of the color filter layer CFL may be located on the light blocking layer BM, and may be arranged so as not to cover the light transmitting areas TA1 and TA2. The color filters CF1, CF2, and CF3 may be arranged to be spaced apart from the edges of the fourth hole OPT4 and the fifth hole OPT5 of the light blocking layer BM. Accordingly, the color filters CF1, CF2, and CF3 may not be arranged around the fourth hole OPT4 and the fifth hole OPT5 of the light blocking layer BM, so that a part of the light blocking layer BM may be exposed. Further, on the light blocking layer BM, the color filter opening CFO may be formed in a region where the color filters CF1, CF2, and CF3 are not located, which is a region overlapping the light transmitting areas TA1 and TA2. The size or area of the color filter opening CFO may be formed to be larger than the sizes or areas of the fourth hole OPT4 and the fifth hole OPT5, and a part of the top surface of the light blocking layer BM may not be covered by the color filters CF1, CF2, and CF3 in the second display area DA2.

According to some embodiments, in the display device 10, different types of light transmitting areas TA1 and TA2 may be located in the second display area DA2. The first light transmitting area TA1 overlaps the fourth opening OPE4 of the pixel defining layer PDL, and thus may transmit most of lights incident from the front of the display device 10. In addition, the lights incident from the side of the display device 10 at a specific angle, rather than from the front thereof, may partially transmit through the first light transmitting area TA1. Here, the transmittance of light incident from the outside of the display device 10 may be affected by the sizes of the light transmitting areas TA1 and TA2. As the sizes of the light transmitting areas TA1 and TA2 become larger, the transmittance of light incident on the second display area DA2 may increase.

Meanwhile, in the display device 10, in the transmittance of light in the second display area DA2, the field of view (FOV) angle may be defined as the angle of incident light having a transmittance of 50% compared to the transmittance of light incident from the front. The FOV angle may increase as the light transmitting areas TA1 and TA2 formed in the second display area DA2 easily transmit light incident from the side and as the areas of the light transmitting areas TA1 and TA2 increase. The display device 10 according to some embodiments includes the second light transmitting area TA2 having a shape surrounding the light blocking pattern BMP overlapping the opening of the pixel defining layer PDL in addition to the first light transmitting area TA1 overlapping the opening of the pixel defining layer PDL, so that the transmittance of light incident from the side may be relatively improved. Further, the display device 10 may have characteristics in which a pixel per inch (PPI) is large due to a large number of pixels arranged in a relatively small area. Accordingly, an empty space where wires of the thin film transistor layer TFTL are not located is reduced and the sizes of the light transmitting areas TA1 and TA2 are reduced. However, the display device 10 includes the second light transmitting area TA2, so that the transmittance in the second display area DA2 may be high. For example, lateral transmittance by the second light transmitting area TA2 may be relatively improved.

Hereinafter, the second light transmitting area TA2 will be described in more detail with reference to other drawings.

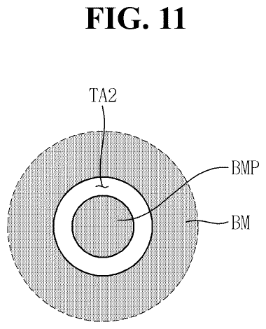

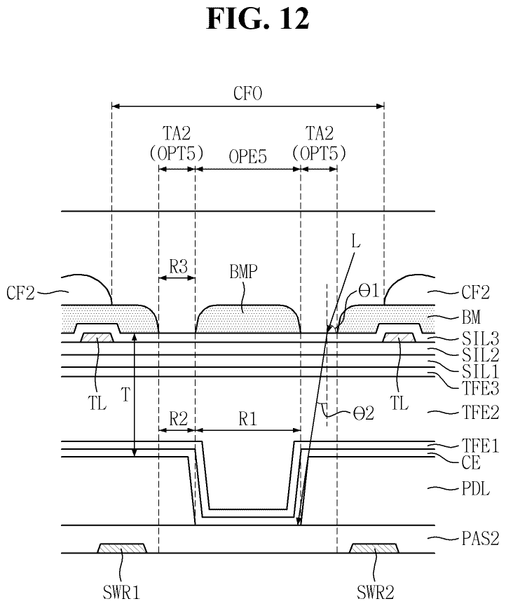

FIG. 11 is a plan view showing the second light transmitting area of the display device according to some embodiments. FIG. 12 is a cross-sectional view showing the second light transmitting area of FIG. 11.

Referring to FIGS. 11 and 12, the second light transmitting area TA2 may be defined as a region between the light blocking layer BM and the light blocking pattern BMP. The light blocking pattern BMP may overlap the fifth opening OPE5, and the second light transmitting area TA2 may surround the light blocking pattern BMP. According to some embodiments, the light blocking pattern BMP and the fifth opening OPE5 of the pixel defining layer PDL may have a circular shape in plan view, and the fifth light transmitting area TA5 or the fifth hole OPT5 may have an annular shape surrounding the light blocking pattern BMP.

The width of the second light transmitting area TA2 or the fifth hole OPT5 may vary depending on a separation distance R2 between the fifth opening OPE5 of the pixel defining layer PDL and the end of the fifth hole OPT5 of the light blocking layer BM and the size of the light blocking pattern BMP. Here, the separation distance R2 between the pixel defining layer PDL and the light blocking layer BM may be set depending on the above-described FOV angle, a thickness T between the light blocking layer BM and the pixel defining layer PDL, and the refractive indices of materials therebetween. For example, light incident at an incident angle θ1 may pass through the second light transmitting area TA2 and be incident at a refraction angle θ2 due to the refractive indices of the materials between the light blocking layer BM and the pixel defining layer PDL. Here, in order to allow the incident light to be incident on at least the fifth opening OPE5 of the pixel defining layer PDL and transmit the display device 10, the separation distance R2 between the pixel defining layer PDL and the light blocking layer BM may have the relationship of the following Eq. (1).

$$R 2 = T * tan ( θ 2 ) \qquad ( 1 )$$

Here, ‘R2’ is the separation distance between the light blocking layer BM in the fifth hole OPT5 and the pixel defining layer PDL in the fifth opening OPE5, ‘T’ is the thickness between the light blocking layer BM and the pixel defining layer PDL, and ‘θ2’ that is the refraction angle of the incident light is a value set by the incident angle θ1 and the refractive indices of the materials between the light blocking layer BM and the pixel defining layer PDL.

The ‘T’ value is set according to thickness specifications, and the material used in the manufacturing process of the display device 10, and the refraction angle 02 may also be set according to the FOV angle or the incident angle θ1. Accordingly, the separation distance R2 between the light blocking layer BM in the fifth hole OPT5 and the pixel defining layer PDL in the fifth opening OPE5 may be fixed, and a width R3 of the second light transmitting area TA2 may vary depending on the size of the light blocking pattern BMP.

According to some embodiments, the size of the light blocking pattern BMP may be the same as a width R1 of the fifth opening OPE5 of the pixel defining layer PDL, and the width R3 of the second light transmitting area TA2 may be the same as the separation distance R2 between the light blocking layer BM in the fifth hole OPT5 and the pixel defining layer PDL in the fifth opening OPE5. The diameter of the portion penetrated by the fifth hole OPT5 and the light blocking pattern BMP in the light blocking layer BM may have a value of ‘2*R2+R1’. However, the present disclosure is not limited thereto, and the width R3 of the second light transmitting area TA2 may vary depending on the diameter of the light blocking pattern BMP.

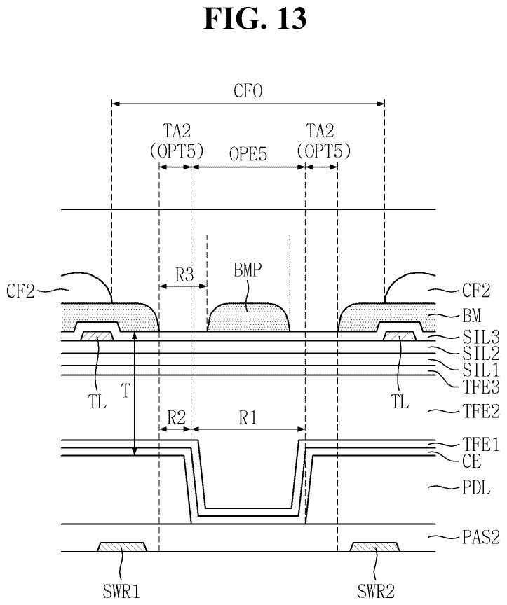

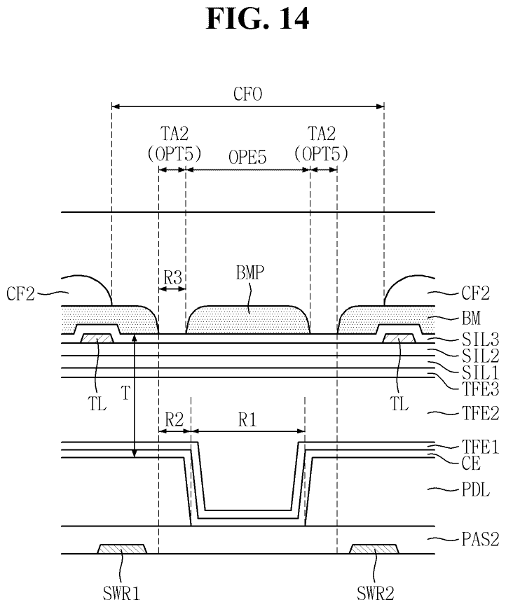

FIGS. 13 and 14 are schematic cross-sectional views of a second light transmitting area of a display device according to some embodiments.

Referring to FIG. 13, in the display device 10 according to some embodiments, the size of the light blocking pattern BMP may be smaller than the width R1 of the fifth opening OPE5 of the pixel defining layer PDL, and the width R3 of the second light transmitting area TA2 may be larger than the separation distance R2 between the light blocking layer BM in the fifth hole OPT5 and the pixel defining layer PDL in the fifth opening OPE5. Referring to FIG. 14, in the display device 10 according to some embodiments, the size of the light blocking pattern BMP may be larger than the width R1 of the fifth opening OPE5 of the pixel defining layer PDL, and the width R3 of the second light transmitting area TA2 may be smaller than the separation distance R2 between the light blocking layer BM in the fifth hole OPT5 and the pixel defining layer PDL in the fifth opening OPE5. According to some embodiments, the size of the light blocking pattern BMP may have a deviation of 5 μm to 10 μm from a diameter R1 of the fifth opening OPE5, and the width R3 of the second light transmitting area TA2 may have a deviation of 2.5 μm to 5 μm from the separation distance R2 between the light blocking layer BM in the fifth hole OPT5 and the pixel defining layer PDL in the fifth opening OPE5. However, also in the case of the above-described embodiments, the diameter of the portion penetrated by the fifth hole OPT5 and the light blocking pattern BMP in the light blocking layer BM may have a value of ‘2*R2+R1’.

The display device 10 according to some embodiments includes the second light transmitting area TA2 in addition to the first light transmitting area TA1 and thus has specifications of a large PPI value, so that the lateral transmittance may be relatively improved even if the areas of the light transmitting areas TA1 and TA2 become small.

Hereinafter, various embodiments of the display device 10 will be described with reference to other drawings.

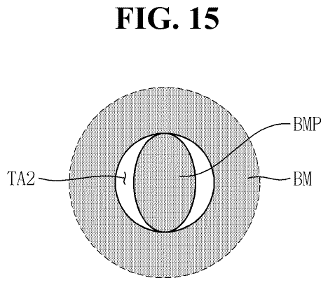

FIGS. 15 to 17 are plan views showing a second light transmitting area of a display device according to some embodiments.

Referring to FIG. 15, according to some embodiments, in the display device 10, the light blocking pattern BMP and the fifth hole OPT5, or the second light transmitting area TA2 may have different shapes. For example, a circular hole may be formed in the light blocking layer BM similarly to the above-described embodiments, and the fifth hole OPT5 and the light blocking pattern BMP may be located therein. However, unlike this, the light blocking pattern BMP may have an elliptical shape, and each of the upper side and the lower side thereof may be in contact with or connected to the light blocking layer BM. The fifth hole OPT5 or the second light transmitting area TA2 may be formed on the left side and the right side of the light blocking pattern BMP. The shape of the fifth opening OPE5 of the pixel defining layer PDL may also have an elliptical shape to correspond to the change in the shape of the light blocking pattern BMP. However, the present disclosure is not limited thereto. The fifth opening OPE5 of the pixel defining layer PDL may not follow the shape of the light blocking pattern BMP.

The display device 10 according to some embodiments may be different from the above-described embodiments in that the light blocking pattern BMP and the fifth hole OPT5 or the second light transmitting area TA2 have different shapes. The second light transmitting area TA2 may have a shape that does not surround the light blocking pattern BMP, and may have different widths depending on locations. Due to the change in the shape of the light blocking pattern BMP and the second light transmitting area TA2, the display device 10 may have a structure that is advantageous for incidence of light incident from the left side and the right side.

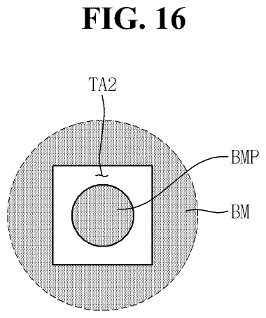

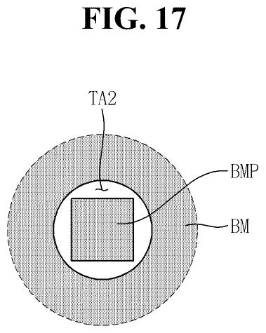

Referring to FIGS. 16 and 17, the shapes of the light blocking pattern BMP and the fifth opening hole OPT5 may be different from each other. For example, as in the embodiments of FIG. 16, the light blocking pattern BMP may have a circular shape in plan view, and the fifth hole OPT5 of the light blocking layer BM may have a quadrilateral edge. On the contrary, in the embodiments of FIG. 17, the light blocking pattern BMP may have a quadrilateral shape in plan view, and the fifth hole OPT5 of the light blocking layer BM may have a circular edge. The width of the second light transmitting area TA2 between the light blocking layer BM and the light blocking pattern BMP may vary depending on locations. As described above, the fifth opening OPE5 of the pixel defining layer PDL, may or may not follow the shape of the light blocking pattern BMP.

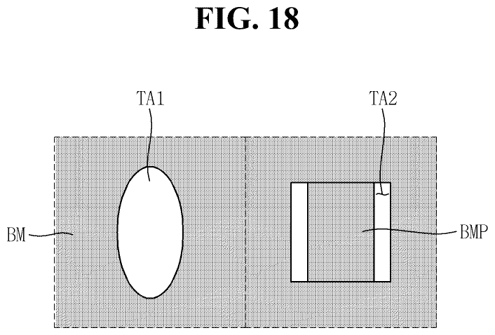

FIG. 18 is a plan view showing a first light transmitting area and a second light transmitting area of a display device according to some embodiments.

Referring to FIG. 18, in the display device 10, the shape of the second light transmitting area TA2 may be designed to be different from the shape of the first light transmitting area TA1. If the shape of the first light transmitting area TA1 is disadvantageous for sensing of lateral incident light, the second light transmitting area TA2 may have a shape advantageous for sensing of lateral light to correspond thereto. For example, in the display device 10, the first transmitting area TA1 or the fourth hole OPT4 of the light blocking layer BM may have an elliptical shape in plan view, and the first light transmitting area TA1 may have a low transmittance for lateral light incident from the left side or the right side compared to a circular shape. In response thereto, the fifth hole OPT5 of the light blocking layer BM, or the second light transmitting area TA2 may be formed on the left side and the right side of the light blocking pattern BMP. The second light transmitting area TA2, which is a light transmitting area for compensating the lateral light transmittance of the first light transmitting area TA1, may not necessarily surround the light blocking pattern BMP and may not necessarily have a uniform transmittance in all four directions. In the display device 10 of FIG. 18, the second light transmitting area TA2 may be formed only on both side surfaces of the light blocking pattern BMP in order to secure the transmittance of the lateral incident light.

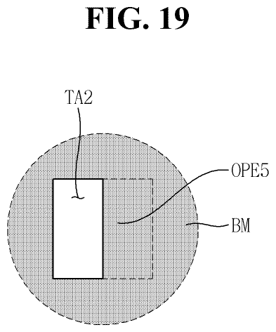

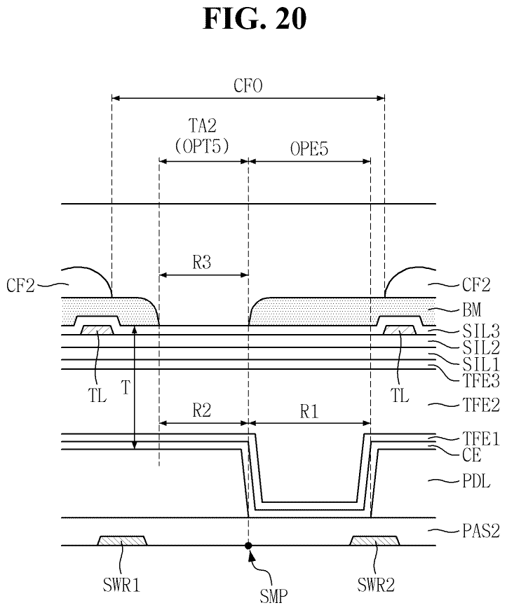

FIG. 19 is a plan view showing a second light transmitting area of a display device according to some embodiments. FIG. 20 is a cross-sectional view showing the second light transmitting area of FIG. 19.

Referring to FIGS. 19 and 20, in the display device 10 according to some embodiments, the fifth opening OPE5 of the pixel defining layer PDL and the second light transmitting area TA2, or the fifth hole OPT5 of the light blocking layer BM may not overlap completely. The fifth opening OPE5 of the pixel defining layer PDL may overlap the light blocking layer BM and may be covered by it. The fifth hole OPT5 of the light blocking layer BM may form the second light transmitting area TA2 and a separate light blocking pattern BMP may not be arranged. Because the second light transmitting area TA2 and the fifth opening OPE5 are arranged to be misaligned without being aligned, the second light transmitting area TA2 may have a shape for securing the transmittance of lateral incident light.

Even if the pixel defining layer PDL and the light blocking layer BM have the arrangement of FIG. 20, the separation distance R2 between the fifth opening OPE5 of the pixel defining layer PDL and the end of the fifth hole OPT5 of the light blocking layer BM may be set according to the thickness T between the light blocking layer BM and the pixel defining layer PDL and the refractive indices of the materials therebetween according to Eq. (1) described above.

According to some embodiments, the fifth opening OPE5 of the pixel defining layer PDL may not be aligned with a center SMP between the signal lines SWR1 and SWR2 whose centers are spaced apart from each other. The pixel defining layer PDL may be arranged to cover the signal lines SWR1 and SWR2, and may have an arrangement in which light incident on the fifth opening OPE5 is not reflected by the signal lines SWR1 and SWR2. In the above-described embodiments, the center SMP between the signal lines SWR1 and SWR2 spaced apart from each other and the center of the fifth opening OPE5 are aligned, but in the display device 10 according to some embodiments, two centers may not be aligned with each other. In the case of a structure in which the incident light that has passed through the second light transmitting area TA2 and the fifth opening OPE5 is not reflected by the signal lines SWR1 and SWR2, the positions of the fifth hole OPT5 of the light blocking layer BM and the fifth opening OPE5 of the pixel defining layer PDL may be variously designed.

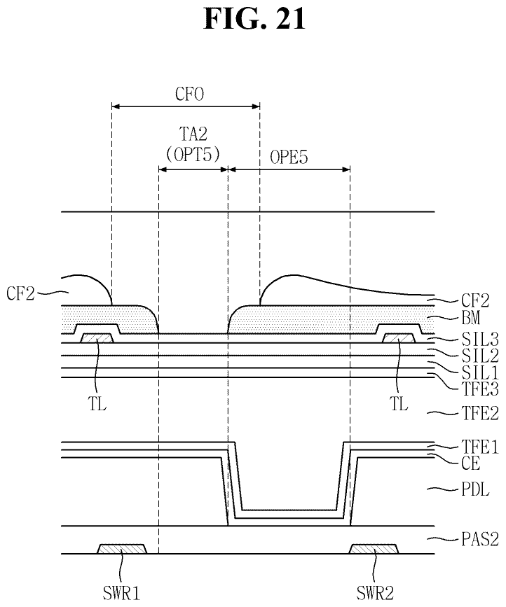

FIG. 21 is a cross-sectional view showing a second light transmitting area of a display device according to some embodiments.

Referring to FIG. 21, the color filter CF located in the second display area DA2 may be arranged so as not to overlap the second light transmitting area TA2 or the fifth hole OPT5 of the light blocking layer BM, and may form the color filter opening CFO. The color filter CF may be arranged so as not to overlap the light blocking pattern BMP, and the light blocking pattern BMP may be located in the color filter opening CFO. Accordingly, the fifth opening OPE5 of the pixel defining layer PDL may also overlap the color filter opening CFO without overlapping the color filter CF. On the other hand, in the display device 10 of FIG. 21, the second light transmitting area TA2 and the fifth opening OPE5 of the pixel defining layer PDL do not overlap without being aligned, so that the color filter CF may not overlap the second light transmitting area TA2 but may overlap the fifth opening OPE5. Because the second light transmitting area TA2 is a hole that transmits light incident from the side, even if the fifth opening OPE5 overlaps the color filter CF, the light that has passed through the second light transmitting area TA2 may be incident on the fifth opening OPE5.

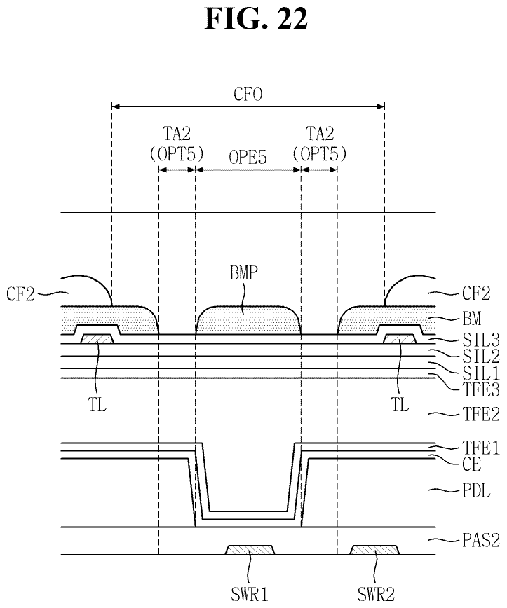

FIG. 22 is a cross-sectional view showing a second light transmitting area of a display device according to some embodiments.

Referring to FIG. 22, according to some embodiments, in the display device 10, any one of the signal lines SWR1 and SWR2 may overlap the fifth opening OPE5 of the pixel defining layer PDL. Further, the light blocking pattern BMP around the second light transmitting area TA2 may overlap at least one of the signal lines SWR1 or SWR2 located thereunder.

Because the light blocking pattern BMP is arranged to overlap the fifth opening OPE5, a region where light is not incident may be formed at a part of the fifth opening OPE5. Even if light incident from the side of the display device 10 passes through the second light transmitting area TA2 and is incident on the fifth opening OPE5, a region where a part of the fifth opening OPE5 is covered by the light blocking pattern BMP may be formed, and light may not be reflected even if the signal lines SWR1 and SWR2 are located in the corresponding region. In the display device 10, it may be advantageous that the signal lines SWR1 and SWR2 are not located in the fifth opening OPE5 in order to secure the transmittance of external incident light. However, in the display device 10, the pixel per unit (PPI) may increase by arranging a large number of pixels in a relatively small area, and the signal lines SWR1 and SWR2 may be located in the region of the fifth opening OPE5 that is covered by the light blocking pattern BMP in order to maximize space utilization in a small area.

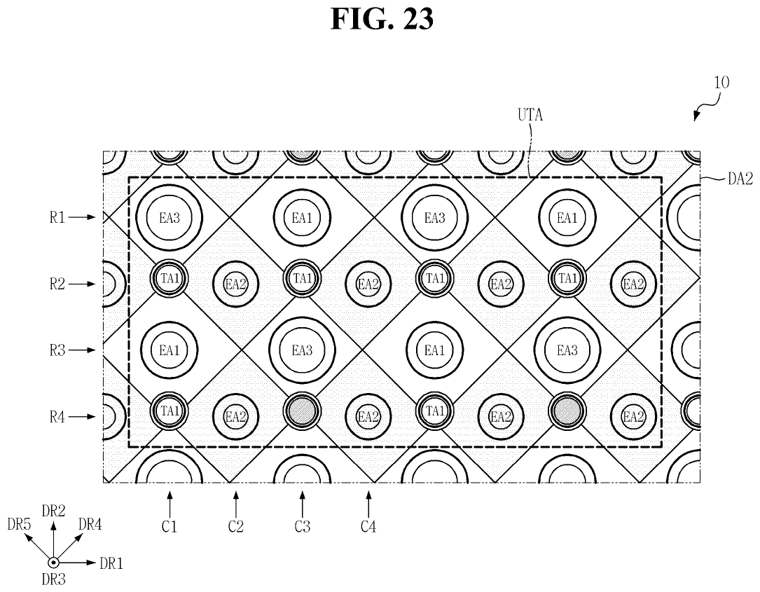

FIGS. 23 to 25 are plan views showing the arrangement of light transmitting areas in a second display area of a display device according to some embodiments.

Referring to FIGS. 23 to 25, according to some embodiments, the number of the first light transmitting area TA1 and the number of the second light transmitting area TA2 per unit area UTA may be different in the second display area DA2 of the display device 10. As described above, in the second display area DA2, the unit area UTA corresponding to four pixel areas may be defined, and a space where eight light transmitting areas TA1 and TA2 may be located may exist in the unit area UTA.

In the display device 10 of FIG. 23, six first light transmitting areas TA1 and two second light transmitting areas TA2 may be located in the unit area UTA. In the unit area UTA, the number of the first light transmitting areas TA1 may be larger than the number of the second light transmitting areas TA2, and the display device 10 may have arrangement of ‘6/8 first light transmitting areas TA1+2/8 second light transmitting areas TA2’.

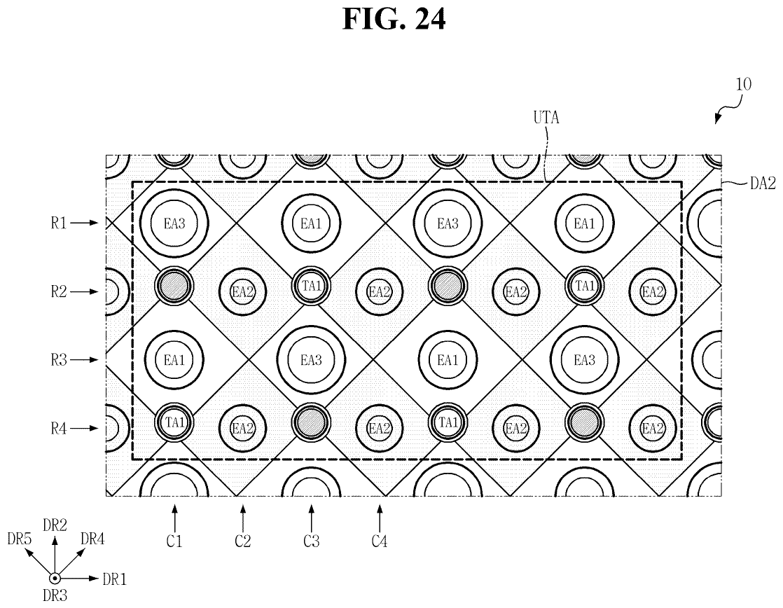

In the display device 10 of FIG. 24, four first light transmitting areas TA1 and four second light transmitting areas TA2 may be located in the unit area UTA. In the unit area UTA, the number of the first light transmitting areas TA1 may be the same as the number of the second light transmitting areas TA2, and the display device 10 may have arrangement of ‘4/8 first light transmitting areas TA1+4/8 second light transmitting areas TA2’.

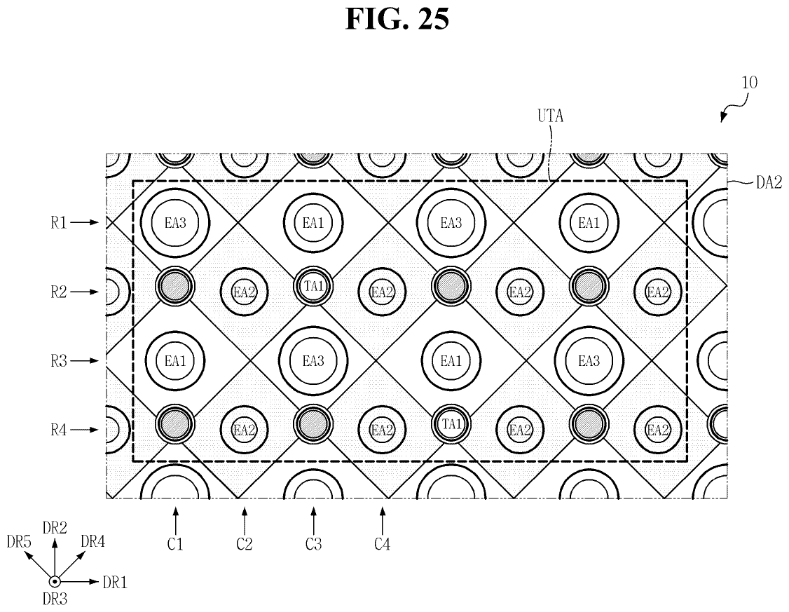

In the display device 10 of FIG. 25, two first light transmitting areas TA1 and six second light transmitting areas TA2 may be located in the unit area UTA. In the unit area UTA, the number of the first light transmitting areas TA1 may be smaller than the number of the second light transmitting areas TA2, and the display device 10 may have arrangement of ‘2/8 first light transmitting areas TA1+6/8 second light transmitting areas TA2’.

In the display device 10, the number and arrangement of the light transmitting areas TA1 and TA2 may be variously designed according to the transmittance of lateral incident light, or a required value of FOV characteristics.

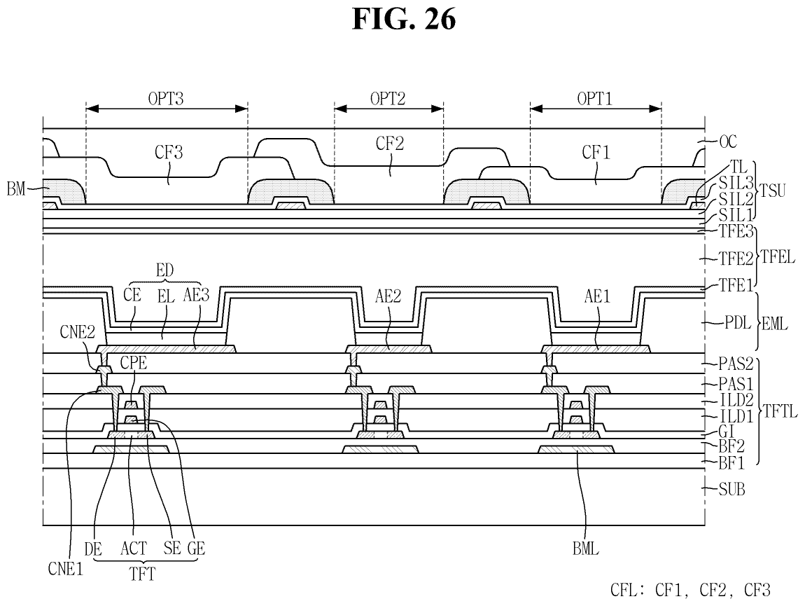

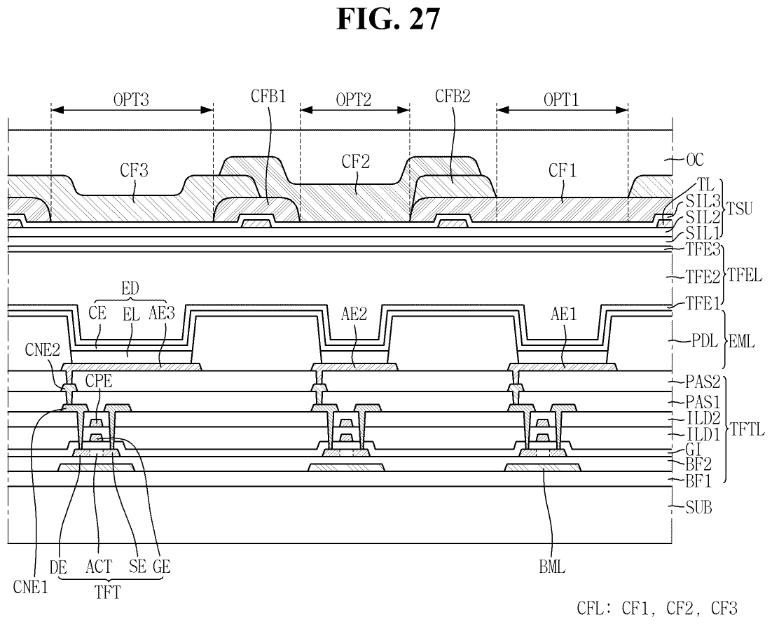

FIGS. 26 and 27 are cross-sectional views of a display device according to some embodiments.

Referring to FIG. 26, in the display device 10 according to some embodiments, the color filters CF1, CF2, and CF3 may be arranged to partially overlap. The plurality of color filters CF1, CF2, and CF3 may overlap different color filters adjacent to each other on the light blocking layer BM. For example, the second color filter CF2 may overlap each of the first color filter CF1 and the third color filter CF3 adjacent on the light blocking layer BM. According to some embodiments, the first color filter CF1 may overlap the third color filter CF3 on the light blocking layer BM, and according to some embodiments, all the first color filter CF1, the second color filter CF2, and the third color filter CF3 may overlap.

Referring to FIG. 27, the display device 10 according to some embodiments may not include the light blocking layer BM and may include color blocking layers CFB1 and CFB2 including the same material as the color filters CF1, CF2, and CF3. The color filters CF1, CF2, and CF3 and the color blocking layers CFB1 and CFB2 may overlap each other between adjacent emission areas EA and may perform the same role as the light blocking layer BM.

For example, the first color filter CF1 may be arranged to overlap the first pixel electrode AE1 and cover the peripheral area thereof. The first color blocking layer CFB1 including the same material as the first color filter CF1 may be located at the boundary between the emission area overlapping the second pixel electrode AE2 and the emission area overlapping the third pixel electrode AE3.

The third color filter CF3 may be arranged to overlap the third pixel electrode AE3 and cover the peripheral area thereof. A part of the third color filter CF3 may be located on the first color filter CF1 and the first color blocking layer CFB1. The first color filter CF1 may be located at the boundary between the emission area overlapping the first pixel electrode AE1 and the emission area overlapping the second pixel electrode AE2, and the second color blocking layer CFB2 including the same material as the third color filter CF3 may be located thereon.

The second color filter CF2 may be arranged to overlap the second pixel electrode AE2 and cover the peripheral area thereof. A part of the second color filter CF2 may be located on the first color blocking layer CFB1 and the second color blocking layer CFB2.

The color filters CF1, CF2, and CF3 or the color blocking layers CFB1 and CFB2 including different color materials may overlap at the boundary between the emission areas overlapping the respective pixel electrodes AE1, AE2, and AE3. Accordingly, they may perform the same role as the light blocking layer BM and may block the transmission of light. The holes OPT1, OPT2, and OPT3 through which light transmits may be formed in a region that does not overlap the color blocking layers CFB1 and CFB2, or the color filters CF1, CF2, and CF3 including different color materials among the color filters CF1, CF2, and CF3.

In concluding the detailed description, those skilled in the art will appreciate that many variations and modifications can be made to the disclosed embodiments without departing from the spirit and scope of embodiments according to the present disclosure. Therefore, the disclosed embodiments of the invention are used in a generic and descriptive sense only and not for purposes of limitation.

What is claimed is:

1. A display device comprising:
a first display area and a second display area around which the first display area is arranged;
a plurality of first openings in the first display area and the second display area and in which light emitting elements are arranged;
a plurality of second openings and third openings in the second display area, in which the light emitting element is not located, and having a smaller size than a size of the first opening;
a light blocking layer comprising a light blocking pattern, a plurality of first holes overlapping the plurality of first openings, a plurality of second holes overlapping the plurality of second openings, and a plurality of third holes around the light blocking pattern that at least partially overlaps a third opening from among the third openings; and
a plurality of color filters in the first display area and the second display area and overlapping the plurality of first holes,
wherein a number of the first holes in the second display area is greater than each of a number of the second holes and a number of the third holes.

2. The display device of claim 1, wherein the third holes are each arranged to surround the light blocking pattern.

3. The display device of claim 2, wherein
the light blocking pattern has a circular shape in a plan view, and
the third hole has a quadrilateral edge in the plan view.

4. The display device of claim 1, wherein the second holes have an elliptical shape in a plan view, and the plurality of third holes are respectively arranged on both sides of the light blocking pattern.

5. The display device of claim 1, wherein each of the third holes does not overlap a corresponding one of the third openings.

6. The display device of claim 1, wherein
the light blocking pattern has an elliptical shape in a plan view, and both ends thereof in a major axis direction are in contact with the light blocking layer, and
a third hole from among the third holes is formed between the light blocking pattern and the light blocking layer.

7. The display device of claim 6, wherein the third hole has a width which varies in the major axis direction of the light blocking pattern.

8. The display device of claim 1, wherein the number of the second holes in the second display area is smaller than the number of the third holes.

9. The display device of claim 1, wherein the number of the second holes in the second display area is greater than or equal to the number of the third holes.

10. The display device of claim 1, wherein the color filters do not overlap the second holes and the third holes.

11. The display device of claim 10, wherein the color filters do not overlap the second openings and the third openings.

12. The display device of claim 1, further comprising a plurality of signal lines in the first display area and the second display area and extending in one direction, wherein
a first opening from among the first openings partially overlaps the signal lines, and
the second openings and the third openings do not overlap the signal lines.

13. The display device of claim 12, wherein a center line between a pair of adjacent signal lines among the plurality of signal lines is not parallel to a center line of the third opening.

14. The display device of claim 12, wherein
the light blocking pattern is integrated with the light blocking layer to cover the third opening, and
a third hole from among the third holes does not overlap a corresponding one of the third openings.

15. The display device of claim 12, wherein some of the signal lines partially overlap the light blocking pattern.

16. A display device comprising:
a substrate comprising a first display area and a second display area around which the first display area is arranged;
a plurality of pixel electrodes on the substrate and spaced apart from each other in the first display area and the second display area;
a pixel defining layer comprising a plurality of first openings on the substrate and the pixel electrodes and overlapping the pixel electrode, and a plurality of second openings and third openings which do not overlap the pixel electrode in the second display area;
an encapsulation layer on the pixel defining layer;
a light blocking layer comprising a plurality of first holes on the encapsulation layer and overlapping the plurality of first openings, a plurality of second holes overlapping the plurality of second openings, and a plurality of third holes around a light blocking pattern overlapping the third opening; and
a plurality of color filters on the light blocking layer and overlapping the first holes without overlapping the second holes and the third holes.

17. The display device of claim 16, wherein
the third holes are defined as a region between the light blocking pattern and the light blocking layer, and
a diameter of the light blocking pattern is equal to a diameter of the third openings, and a width of the third holes is equal to a separation distance between the third openings and the light blocking layer.

18. The display device of claim 16, wherein a diameter of the light blocking pattern is different from a diameter of the third openings.

19. The display device of claim 16, wherein
the light blocking pattern is integrated with the light blocking layer to overlap the third openings, and
the third holes do not overlap the third openings.

20. The display device of claim 19, further comprising a plurality of signal lines on the substrate and arranged so as not to overlap the second holes and the third holes,
wherein a center line of a pair of the signal lines adjacent to each other is not parallel to a center line of the third openings.
